(19) United States
(12) Patent Application Publication
(10) Pub. No.: US 2014/0373751 A1
(43) Pub. Date: Dec. 25, 2014

(54) NIOBIUM-BASED COATINGS, METHODS OF PRODUCING SAME, AND APPARATUS INCLUDING SAME

(71) Applicants: Christopher A. Schuh, Ashland, MA (US); Rafael A. Mesquita, Cambridge, MA (US)

(72) Inventors: Christopher A. Schuh, Ashland, MA (US); Rafael A. Mesquita, Cambridge, MA (US)

(21) Appl. No.: 14/369,611

(22) PCT Filed: Dec. 28, 2012
(86) PCT No.: PCT/US12/72029

§ 371 Date: Jun. 27, 2014

Related U.S. Application Data
(60) Provisional application No. 61/581,438, filed on Dec. 29, 2011.

(51) Int. Cl. C23C 14/06; C23C 14/34; C23C 14/35

(52) U.S. Cl. CPC C23C 14/0635; C23C 14/0664; C23C 14/35; C23C 14/3414
USPC 106/286.1; 204/192.15

(57) ABSTRACT

Provided in one embodiment is a coating composition, comprising: a first compound comprising a niobium element, a carbon element, and at least one non-metal element that is capable of forming a second compound with the niobium element or a combination of the niobium element and the carbon element.

All publications, patents, and patent applications cited in this Specification are hereby incorporated by reference in their entirety.

### RELATED APPLICATION

This application claims priority from U.S. Provisional Application Ser. No. 61/581,438, filed Dec. 29, 2011, which is hereby incorporated by reference in its entirety.

### BACKGROUND

Since the 1960s hard coatings have been applied to reduce wear and improve friction characteristics in connection with various industrial equipment (e.g., machinery) and machining implements (e.g., cutting tools). Due to its relatively high hardness, one of the first compounds employed for such applications was titanium carbide (TiC). This compound may be applied by Chemical Vapor Deposition (CVD); however, the relatively high temperature of the CVD process is generally not suitable for many steel substrates, thereby restricting the use of the CVD process to solid carbide tools. Alternatively, Physical Vapor Deposition (PVD) was developed as an effective way to reduce the processing temperature for applied coatings to less than 550° C., thereby enabling titanium carbide coatings on high alloy steels.

In the PVD process nitriding reactions are induced more easily; thus, nitrides gradually replaced carbides as alternative coatings, with titanium nitride (TiN) being the most widely used compound due to its similarity to TiC. Presently, PVD TiN compounds often are modified with Al to increase thermal stability. As a result of this trend, there is a significant emphasis in the literature relating to PVD coatings directed to the study of nitrides, with the number of studies on carbides being much smaller.

### SUMMARY

Notwithstanding a conventional focus in the relevant art on nitride coating, the present inventors have recognized and appreciated that there are a number of alternative carbide systems that provide useful coating characteristics (e.g., high strength and thermal stability), even though they have not been widely studied. One noteworthy example recognized by the present inventors is niobium carbide, which as a bulk compound, exhibits a hardness above 20 GPa and a melting temperature above 3000° C. To date, however, there are no reports on the mechanical properties of NbC produced by PVD, such as hardness and the effect of process variables.

With respect to PVD coatings generally, options to the microstructure design of PVD coatings mainly are related to hardness. However, the present inventors further have recognized and appreciated that many end-life mechanisms of tools and coatings are related to a lack of toughness and not necessary purely abrasive (e.g., hardness dependent) failures. Unfortunately, there has been no report to date that a niobium-based coating material may be deposited by an energy efficient technique while the coating still maintains desirable material properties.

In view of the foregoing, various inventive embodiments described herein relate generally to niobium based coatings (e.g., for industrial applications such as cutting or forming tools), methods for producing such coatings, and various apparatus including such coatings.

One embodiment of the present invention is directed to a coating composition, comprising: a first compound comprising a niobium element, a carbon element, and at least one non-metal element that is capable of forming a second compound with the niobium element or a combination of the niobium element and the carbon element.

Another embodiment is directed to a composition, comprising: a first compound comprising a first transition metal element and a carbon element; and at least one second transition metal element that has a solubility lower than 10 atomic percent in the first compound.

Another embodiment is directed to a method of forming a composition, the method comprising: A) providing a substrate; and B) disposing on the substrate a mixture of elements to form the composition, the mixture comprising niobium, carbon, and at least one additional element, wherein B) involves deposition under a condition involving a processing intensity parameter.

Another embodiment is directed to a method of forming a composition, the method comprising: A) sputtering, under a condition involving at least one processing intensity parameter comprising at least one of an applied bias and deposition pressure, a mixture of niobium, carbon, and at least one additional element onto a substrate so as to form the composition; and B) controlling the processing intensity parameter so as to affect at least one property of the composition.

Another embodiment is directed to a coating composition formed by a method comprising: A) disposing on a substrate a mixture of elements to form the coating composition, wherein the disposing involves deposition under a condition involving a processing intensity parameter; and wherein the coating composition comprises a first compound comprising a niobium element, a carbon element, and at least one non-metal element that is capable of forming a second compound with the niobium element or a combination of the niobium element and the carbon element.

Another embodiment is directed to a coating composition formed by a method comprising: A) disposing on a substrate a mixture of elements to form the coating composition, wherein the disposing involves deposition under a condition involving a processing intensity parameter; and wherein the coating composition comprises a first compound comprising a first transition metal element and a carbon element; and at least one second transition metal element that has a solubility lower than 10 atomic percent in the first compound.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### REFERENCES

F. I. Ajami, R. K. Maccrone, J. the Less-Common Met. 38 (1974) 101.
A. Bendavid, P. J. Martin, T. J. Kinder, E. W. Preston, Surf. Coat. Tech. 163/164 (2003) 347.
J M. Benegra, D. G. Lamas, M. E. F. de Rapp, N. Mingolo, A. O. Kunrath, R. M. Souza, Thin Solid Films 494 (2006) 146.
D. Bhaduri, A. Ghosh, S. Gangopadhyay, S. Paul, Surf. Coat. Tech. 204 (2010), 3684.
N. J. M. Carvalho, E. Zoestbergen, B. J. Kooi, J. Th. M. De Hosson, Thin Solid Films 429
X. Chu, M. S. Wong, W. D. Sprout, and S. L. Rohde, S. A. Barnett. J. Vac. Sci. Tech. A, 10 (1992) 1604.
A. J. Detor, A. M. Hodge, E. Chason, Y. Wang, H. Xu, M. Conyers, A. Nikroo, A. Hamza, Acta Mater. 57 (2009) 2055.
Foreign Technology, Met. Sci. Heat Treat., 4 (1962) 210.
Guha J. P., Kolar D. 29 (1972) 33.
H. E. Hintermann, Wear 47 (1978) 407.
U. Helmersson, S. Todorova, S. A. Barnett, and J. E. Sundgren, L. C. Market and J. E.
Greene. J. Appl. Phys. 62 (1987) 481.
L. Hultman, L. R. Wallenberg, M. Shinn and S. A. Barnett. J. Vac. Sci. Tech. A. 10 (1992) 1618.
C. C. Koch, O. B. Gavin, C. G. McKamey and J. O. Scarbrough. Appl. Phys. Letters. 43 (1983) 1017.
B. M. Kramer, Thin Solid Films 108 (1983) 117.
P. Y. Lee and C. C. Koch. J. Non-Cryst. Sol. 94 (1987) 88.
R. Machunze, G. C. A. M. Janssen. Thin Solid Films, 517 (2009) 5888.
P. H. Mayrhofer, C. Mitterer, L. Hultman, H. Clemens. Prog. Mater. Sci. 51 (2006) 1032.
R. A. Mesquita, C. A. Barbosa, E. V. Morales, and H.-J. Kestenbach. Met. Mater. Trans. A, 42 (2011), 461.
C. Mitterer, P. H. Mayrhofer, M. Beschliesser, P. Losbichler, P. Warbichler, F. Hofer, P. N. Gibson, W. Gissler, H. Hruby, J. Musil, J. Vleek. Surf. Coat. Tech. 120/121 (1999) 405.
M. A. Moram, Z. H. Barber, C. J. Humphreys, T. B. Joyce and P. R. Chalker. J. Appl. Phys., 100 (2006), p. 023514.
K-H Müller, J. Appl. Phys. 62 (1987) 1796.
W. D. Manz, D. Hofmann, K. Hartig, Thin Solid Films 96 (1982) 79.
A. Nino, A. Tanaka, S. Sugiyama, H. Taimatsu, Mater. Trans. 51 (2010) 1621.
M. Nordin, M. Larsson, S. Hogmark. Wear. 232 (1999) 221.
S. PalDey, S. C. Deevi, Mater. Sci. Eng. A 342 (2003) 58.
I. Petrov, F. Adibi, J. E. Greene, L. Hultman, J.-E. Sundgren, Appl. Phys. Lett., 63 (1993) 36.
I. Petrov, L. Hultman, U. Helmersson, J.-E. Sundgreen. Thin Solid Films, 169 (1989) 299.
G. Roberts, G. Krauss, R. Kennedy, Tool Steels, 5^{th} ed., ASM International, Materials Park, Ohio, 1998, p. 220-223.
C. S. Sandu, R. Sanjines, M. Benkahoul, F. Medjani and F. Levy. Surf. Coat. Tech. 201 (2006) 4083.
W. Schintlmeister, 0. Pacher and K. Pfaffinger. J. Electrochem. Soc. 123 (1976) 925.
W. Schintlmeister, W. Wallgram, J. Kanz. Thin Solid Films 107 (1983) 117.
W. Schintlmeister, W. Wallgram, J. Kanz, K. Gigl, Wear 100 (1984) 153.
O. I. Shulishova. Izvestiya Akademii Nauk SSSR, Seriya Neorganisheskiye Materialy, Vol. 2, N. 8, 1966, pp. 1434-1438. Translation to English by NASA report NASA TT F-10,446.
W. D. Sproul, R. Rothstein, Thin Solid Films 126 (1985) 257.
C. Subramanian, K. N. Stratford, T. P. Wilks and L. P. Ward. J. Mater. Process. Tech., 56 (1996) 385.
T. Takahashi, K. Sugiyama, K. Tomita. J. Electrochem. Soc. 114 (1967) 1231.
A. Thornton Ann. Rev. Mater. Sci. 7 (1977) 239.
M. Van Stappen, L. M. Stals, M. Kerkhofs, C. Quaeyhaegens, Surf. Coat. Tech. 74/75 (1995) 629.
Krystyna Wokulska, “X-ray determination of the thermal expansion of TiN, TiC and Ti(N,C) crystals”, Proc. SPIE 3179, 176 (1997).
P. K. Wright and E. M. Trent, Metal Cutting, 4^{th} ed. Butterworth Heinemann, 2000.

### BRIEF DESCRIPTION OF THE DRAWINGS

A skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIGS. 1(a) and 1(b) show variation in deposition rate and structural integrity/soundness, respectively, of a deposited film as a function of a bias voltage used in a sputtering process in one embodiment.

FIG. 2 shows data for mechanical properties, in terms of sputtering conditions of bias and total pressure, of a coating in one embodiment. The open dots represent the coatings sputtered with higher pressure (0.67 Pa, at 70 v) and the others with lower pressure (0.40 Pa), with bias values of 0 v, 70 v, and 150 v.

FIG. 3 provides X-ray data showing a single phase cubic carbide and the dislocation of peaks to lower diffraction angles due to compressive residual stress (see FIG. 4).

FIG. 4 illustrates the effects of the “process intensity” on the hardness and compressive residual stress.

FIGS. 5(a)-5(c) illustrate surface roughness for each sputtering condition of NbC: (a) zero bias, (b) 70 v bias and 0.40 Pa total pressure, (c) 70 v bias and 0.67 Pa total pressure. Images are obtained by scanning probe microscopy (top images) and scanning electron microscopy (bottom images); the roughness values refer to the average roughness as determined by an nanoindenter.

FIGS. 6(a)-6(b) provide TEM micrographs of NbC sputtered under (a) zero volt bias and (b) high bias conditions (70 v).

FIG. 7 shows TEM micrographs of microstructures of (a) NbC prepared with zero volt Bias and (b) NbC_{0.60}N_{0.40}, evaluated in thicker lamellas (about 100 nm) than in FIG. 6.

FIG. 8 shows X-ray diffraction data for compositions deposited on steel in one embodiment.

FIG. 9 shows the monotonic dependence of lattice constant on N-content in one embodiment. Black dots show the linear change observed from powder diffraction files (PDF) for NbC and NbN, including intermediary compounds NbC_{0.5}N_{0.5}. Open triangle dots represent the linear plot of the measured lattice constant from present data, plotted according to best fit of a linear regression. The error bars represent the standard deviation from the Rietveld method used to calculate the lattice constants.

FIGS. 10(a)-10(b) show mechanical properties of the coatings versus the nitrogen content calculated according to FIG. 1 for the zero volts bias condition in one embodiment.

FIGS. 11(a)-11(b) show microstructure of (a) a NbC PVD film and (b) a NbC_{0.6}N_{0.4} PVD film, both sputtered without applied bias. The bright and dark field images show the similar columnar grain microstructure and grain size of both compositions. Part of the substrate is present in the bright field image of FIG. 11(b).

FIG. 12 shows deposition rate measured for sputtering with single Ni and NbC guns on a masked glass slide in one embodiment.

FIGS. 13(a)-13(b): Auger peaks for (a) niobium and (b) carbon for NbC and NbC+30 at % Ni (or “NbC+30Ni”).

FIGS. 14(a)-14(b) show X-ray diffraction data for several compositions in one embodiment: (a) deposited on steel; (b) a zoom-in version of (a) showing a comparison of data between 37.5° and 52.5° deposited on silicon wafers to avoid the overlap of Fe (110) reflections and Ni (111).

FIGS. 15(a)-15(d) provide transmission electron microscopy (TEM) images, showing the grain refinement effect of nickel: (a) bright (i) and dark field (ii) images for NbC+30 at % Ni 0 v bias, original magnification 250,000×; (b) detail of region highlighted in (a) at 600,000× magnification; (c) detail of the diffraction pattern shown in (a); the lines for NbC and FCC Ni are marked; (d) NbC 0 v bias, without addition of nickel, shows columnar microstructure as seen in conventional PVD film.

FIGS. 16(a)-16(b) show mechanical properties of coatings with NbC and Ni: (a) shows the effect of the process intensity (pressure x bias) on the hardness when Ni is at 30 at %; and (b) shows the effect of Ni-content (at %) on hardness and Young's modulus at high bias.

FIGS. 17(a)-17(d) show a comparison of corner cracks for pure (a)-(b) NbC and (c)-(d) NbC+30 at % Ni as shown in FIG. 15(a), both sputtered with zero volts bias and with a hardness of about 16 GPa for the NbC and 12 GPa for NbC+30 at % Ni. Note that (b) and (d) are zoom-in images of (a) and (c), respectively.

FIGS. 18(a)-18(b) provide phase diagrams for a Ni—Nb—C system: (a) ternary diagram; the compositions with 10 at % and 30 at % Ni are marked by arrows; (b) binary diagram for NbC and Ni phases in which the low solubility of Ni in NbC is marked by an arrow.

### DETAILED DESCRIPTION

Following below are more detailed descriptions of various concepts related to, and embodiments of, inventive niobium-based coatings, methods of producing same, and apparatus including same. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

Niobium-Based Coating Compositions Containing Non-Metal Elements

One embodiment provides a niobium-containing coating that may be used in industrial applications such as cutting or forming tools. The coating may comprise a coating composition, including a Nb-containing composition or a Nb-based composition. For example, the coating may consist essentially of a coating composition; alternatively, the coating may consist of a coating composition. In one embodiment, the coating may comprise a niobium-based composition. The composition may have one phase or a plurality of phases.

The term “phase” may be readily appreciated by one of skill in the art. In one embodiment, “phase” may refer to a phase that is found in a thermodynamic equilibrium diagram. Different phases may have different physical and/or chemical properties. For example, an element, solid solution, and compound are respective distinct phases. Thus, in one embodiment, the composition may have a single phase, such as a single solid solution, a single compound, or a single element. In another embodiment, the composition may have multiple phases, such as a mixture of (any of) solid solution, compound, and material in its elemental form.

The term “element” in some embodiments may refer to an element found in the Periodic Table. For example, a niobium element may refer to “Nb” as found in the Periodic Table. The term “X-based” composition (X referring to an element) in some embodiments may refer to a composition containing at least a significant portion of element X—e.g., at least about 40%, about 50%, about 60%, about 70%, about 80%, about 90%, about 95%, about 99%, about 99.5%, about 99.9%. Percentages may refer to volume or weight percentages, depending on the context. The term “pure” when referring to a composition in some embodiments may refer to at least commercial-grade purity, taking into account certain amounts of inevitable, incidental impurity. For example, a “pure” element may refer to, for example, at least about 95% purity, at least about 99%, at least about 99.5%, at least about 99.9%, at least about 99.99% purity.

In some embodiments, a niobium-based coating composition may include at least one non-metal element. For example, in some embodiments, the coating composition may include a first compound comprising a niobium element, a carbon element, and at least one non-metal element that is capable of forming a second compound with the niobium element or a combination of the niobium element and the carbon element. In one aspect, the compound may refer to a chemical compound. For example, in one embodiment, the compound may comprise niobium carbide. In another embodiment, the first compound may consist essentially of a niobium element, a carbon element and a non-metal element. In another embodiment, the first compound may consist of these aforedescribed elements.

The non-metal element may be any non-metal element that may be found in the Periodic Table. A non-metal element may be one that is found in, for example, any of Groups 13-17 in the Period Table. For example, the element may be carbon, nitrogen, phosphorus, oxygen, and the like. Accordingly, in one embodiment, the first compound may be niobium carbonitride.

The niobium carbonitride constituting a coating composition according to some embodiments may have various stoichiometric numbers for each of its elemental constituents in the chemical formula; for example, the niobium carbonitride may be NbC_{0.5}N_{0.5}, NbC_{0.6}N_{0.4}, or NbC_{0.4}N_{0.6}. Other combinations of the stoichiometric numbers are suitable for various implementations. In one embodiment, the niobium element and the carbon element may be present in a ratio of approximately 1:1. Other ratios, such as any ratio between 1:0.5 and 1:1.5, are possible. In another embodiment, the niobium element and the sum of the carbon element and the non-metal element may be present in a ratio of approximately 1:1. Similarly, other ratios, such as ratios between 1:0.5 and 1:1.5, are possible. The ratio may refer to a ratio of “content,” which in some embodiments herein may refer to either volume (or atomic) percentage or weight percentage, depending on the context. In one embodiment, the ratio may refer to volume (or atomic) content.

In some embodiments, it is desirable to have a non-metal element as one that is capable of forming a second compound with the niobium element, alone, or with a combination of the niobium element and the carbon element. Accordingly, in one example wherein the non-metal element is nitrogen, the second compound may be NbN or Nb(C,N). Other non-metal elements may also be employed. In some embodiments, a compound having elements of niobium, carbon, and at least one non-metal may be formed by, for example, substituting at least some of the carbon atoms with the at least one non-metal atoms. The second compound may be the same or different from the first compound. In one embodiment, the second compound is different from the first compound. Although the non-metal element may form a second compound that is different from the first compound, the second compound need not co-exist with the first compound in the coating composition (although they may co-exist in some embodiments). In other words, the capability of the non-metal element in one embodiment to form a compound with the Nb, or Nb together with C, refers to its material property and not necessarily the co-existence of the two compounds. In fact, in some embodiments, the coating composition may consist essentially of the first compound. In another embodiment, the coating composition may consist of the first compound.

The Nb-based coating compositions containing a non-metal element according to various inventive embodiments described herein may have a plurality of desirable material properties (e.g., physical properties and/or chemical properties). The non-metal element may be any of the non-metal elements as aforedescribed. The coating composition provided in one embodiment may have relatively low porosity. As a result, in some embodiments the coating composition preferably does not exhibit Type I morphology, which generally refers to a porous film. In some embodiments, a Type I morphology refers to a morphology including tapered crystals with domed tops that are separated by voided boundaries, as defined by Thornton. In one embodiment, a low ratio of substrate to melting temperature of the coated compound (Ts/Tm) leads to films of Type I morphology, which are less dense and have compromised mechanical properties. Other types of morphologies, such as Type II and Type III (Thornton) morphologies have higher density than Type I morphology. These alternative denser morphologies may also be produced by changing the ratio of (Ts/Tm). In one aspect, the sensitivity of NbC to this effect may be significantly higher than for nitrides such as TiN or CrN, due to the higher melting point of NbC, which is about 3800 K, in comparison to 3200 K for TiN and 1800 K for CrN.

In some embodiments a low porosity may give rise to desirable mechanical properties for the coating or coating composition. For example, various inventive coating compositions described herein have a relatively high hardness value—e.g., at least approximately 5 GPa, at least approximately 10 GPa, at least approximately 15 GPa, at least approximately 20 GPa, at least approximately 30 GPa, at least approximately 40 GPa. Additionally (and optionally), various inventive coating compositions described herein have a relatively high Young's modulus—e.g., at least approximately 200 GPa, at least approximately 250 Pa, at least approximately 300 GPa, at least approximately 350 GPa, at least approximately 400 GPa, at least approximately 450 GPa, at least approximately 500 GPa.

Coating compositions according to the present disclosure may have other desirable mechanical properties. For example, a given composition may have a compressive residual stress and/or strain (for example, as a result of processing) of at least approximately 2.0 GPa, at least approximately 3.0 GPa, at least approximately 4.0 GPa, at least approximately 6.0 GPa, at least approximately 8.0 GPa, at least approximately 10.0 GPa. The residual compressive stress may be calculated by any techniques readily known.

Coating compositions described herein also may have high thermostability, in addition to the mechanical properties. Thus, the addition of a non-metal element, such as nitrogen (N), may be used to tailor the material properties of a coating composition. Depending on the context, the tailoring of material properties in one embodiment may refer to either increasing or decreasing the value or magnitude of the material properties as a function of the content of the added non-metal element.

The relationship between content of the non-metal element and the material property (of the coating composition) may be any type of relationship, depending on the property. For example, in one embodiment wherein the non-metal is N, the coating composition may exhibit a monotonic relationship between at least some of its material properties (e.g., mechanical and/or thermal properties), and the non-metal content (for example, N). A monotonic dependence in some embodiments may refer to a function of which the first derivative does not change sign. For example, a monotonic dependence in one embodiment may be a linear dependence. In one embodiment, the material property may be at least one of (i) a lattice constant; (ii) a hardness; (iii) a Young's modulus; (iv) a thermal expansion coefficient; (v) a thermal conductivity; and (vi) a fracture toughness. Note that while the examples described above references N as the non-metal element, the aforedescribed properties and the relationship are applicable to other non-metal elements.

Coatings having the various coating composition described herein may have various types of microstructures. In one embodiment, wherein the composition comprises Nb, C, and a non-metal element (e.g., niobium carbonitride), the compositions or the resulting coating may have a columnar grain microstructure. In this embodiment, the grain may have at least one dimension in the micrometer range or smaller, such as the nanometer range. The dimension may refer to, for example, the width of the grain. In some embodiments, the average grain width of the coating composition may be between approximately 2 nm and approximately 150 nm, between approximately 5 nm and approximately 100 nm, between approximately 5 nm and approximately 50 nm, between approximately 10 nm and approximately 40 nm, between approximately 15 nm and approximately 30 nm.

Niobium-Based Coating Compositions Containing Transition Metal Elements

One embodiment provides a coating, which comprises a coating composition; the coating composition may be a Nb-containing composition or a Nb-based composition. The coating composition may contain a transition metal element, instead of a non-metal element, in combination with a Nb-containing material. The term “transition metal” is readily known and may refer to any element in Groups 3-12 in the Periodic Table. For example, one embodiment provides a coating composition, which includes a first compound comprising a first transition metal element and a carbon element, and at least one second transition metal element that would have a low solubility in the first compound. In some embodiments, the first transitional metal element may be niobium. Accordingly, in one embodiment, the first compound may comprise (or be) niobium carbide.

The second transition metal element in the various inventive embodiments may be the same as or different from the first transition metal element. In one embodiment, the two transition metal elements are different from each other. In some embodiments, it is preferred that the second transition metal element has a low solubility in the first compound—e.g., less than or equal to approximately 15%, less than or equal to approximately 10%, less than or equal to approximately 5%, less than or equal to approximately 2%. The percentage may refer to volume (atomic) or weight percentage, depending on the context. In one embodiment, the percentage refers to atomic percentage. In one embodiment, the second transition metal element may be at least one of nickel and cobalt. In one embodiment, the second transition metal element is Ni.

Because the second transition metal element has a low solubility in the first compound, in some embodiments the coating compositions may have more than one phase, such as two, three, four, or more, phases. In particular, in some embodiments, the second transition metal element may phase-separate from the first compound (that includes the first transition metal element and the carbon element). For example, at least some of the second transition metal element may form a phase with the first transition metal element or the carbon element, which phase is different from another phase comprising the first transition metal element and the carbon element. In one embodiment, the second transition metal may form (or be in the form of) a solid solution (e.g., Ni—Nb) with at least some of the first transition metal element while the phase formed by (or comprising) the first transition and carbon is a compound. The solid solution may co-exist with another phase, which may be a non-solid solution phase—e.g., a compound formed by the first transition metal element and the carbon element (e.g., niobium carbide). As a result, the coating composition in some embodiments may resemble a composite of co-existing distinct phases.

As described above, the two phases in the coating composition may have different materials properties. For example, in the aforementioned embodiment with a (solid) solution of the first and second transition metal elements, the first phase may have a hardness value that is different from that of the compound phase comprising the first transition metal element and the carbon element. For example, the hardness value of the solid solution may be lower than that of the compound. Alternatively, the former may be higher than the latter. In one embodiment wherein the solid solution has a lower hardness value than does the compound, the introduction of the second transition-metal element into the first compound improves the overall fracture toughness and/or ductility (or any other related properties) of the coating composition. In other words, a composition with the addition of the second transition metal element may have a higher fracture toughness (and/or ductility) compared to the same composition without the at least one second transition element. The fracture toughness and/or ductility (and other related properties) may be measured by any suitable techniques. For example, in one embodiment, the comparison of fracture toughness between two samples may be performed by a comparison of the length of cracks after an indentation (by, for example, microindentation or nanoindentation, as described below). A high fracture toughness may be represented by fewer and/or shorter cracks observed on the sample after indentation.

The second transition metal element may be present in the presently described coating composition at any suitable amount/content. For example, the second transition metal element may be present at a range that is less than or equal to approximately 40 atomic %, less than or equal to approximately 30 atomic %, less than or equal to approximately 20 atomic %, less than or equal to approximately 10 atomic %. In some instances, a content of the second transition metal element outside of the range in one embodiment may result in a coating composition and/or coating that has mechanical properties (e.g., fracture toughness and/or ductility) lower in comparison to a coating composition and/or coating having the second transition metal element inside the range.

In one embodiment, the addition of a second transition element into a (first) compound that contains Nb and C to form a coating composition may result in change in material properties (in addition to fracture toughness and/or ductility). For example, in one embodiment wherein the second transition metal element is nickel, the addition of nickel may result in grain refinement of the microstructure of overall the coating composition. In one embodiment, grain refinement may refer to reducing the (average) size of the grain in a material.

In one aspect, in one embodiment wherein the coating composition contains Ni, which is in a phase distinct from the first compound, may prevent growth of the grains of the first compound in the coating composition, thereby resulting in a finer grain structure (or “grain refinement”). In one embodiment, the microstructure of this coating composition may differ from that in the previously described embodiments wherein the coating composition comprises Nb, C, and a non-metal element. For example, in contrast to a columnar grain structure of the aforedescribed embodiment, the coating composition comprising two transition metal elements may have a non-columnar structure. For example, it may have an at least substantially equiaxed grain structure, such as an entirely equiaxed grain structure.

These non-columnar grains in some embodiments may have a grain size less than or equal to approximately 100 nm—e.g., less than or equal to approximately 50 nm, less than or equal to approximately 20 nm, less than or equal to approximately 15 nm, less than or equal to approximately 10 nm, less than or equal to approximately 5 nm. Because the grains are equiaxed, or at least substantially equiaxed, the grain size may refer to the size of and dimension of the grain. The grain size described herein may refer to average grain size.

In one embodiment wherein the coating comprises two transition metal elements and carbon element, the coating composition may have a high hardness value—e.g., at least approximately 5 GPa, at least approximately 10 GPa, at least approximately 15 GPa, at least approximately 20 GPa, at least approximately 30 GPa, at least approximately 40 GPa. Additionally (or optionally), the coating composition may have a high Young's modulus—e.g., at least approximately 100 GPa, at least approximately 150 GPa, at least approximately 200 GPa, at least approximately 250 GPa, at least approximately 300 GPa, at least approximately 350 GPa, at least approximately 400 GPa.

Coating compositions described herein also may have high thermal stability, in addition to the mechanical properties. This addition of transition metal, such as Ni, may alter the material properties of a coating composition. For example, the addition of Ni may reduce the magnitude of certain material properties of the coating composition. On the other hand, the addition may increase the magnitude of certain other material properties of the coating composition. The relationship between the Ni content (or Ni-addition) may be any type of relationship, depending on the property. In one embodiment, the coating composition may exhibit a monotonic relationship (e.g., linear) between at least some of its material properties (e.g., mechanical and/or thermal properties) and the addition of non-metal element. In one embodiment, some of these material properties may be at least one of (i) a lattice constant; (ii) a hardness; (iii) a Young's modulus; (iv) a thermal expansion coefficient; (v) a thermal conductivity; and (vi) a fracture toughness. Note that while the examples described above references Ni as the non-transition metal element, the aforedescribed properties and the relationship are applicable to other transition metal elements.

Making of Coating Compositions

Coatings compositions according to various embodiments aforedescribed may be made via commonly understood fabrication techniques.

In one embodiment, coating compositions may be fabricated by any suitable techniques, such as sputtering or vapor deposition (including physical vapor deposition (PVD)). The deposition may be accomplished by any known techniques and/or equipment, (e.g., via a magnetron sputtering unit). In one embodiment, the materials to be deposited to form the coating may be any mixture containing niobium or its alloy and/or compound—e.g., pure NbC, pure Nb(C,N), multilayer NbC/TiN, and NbC or Nb(C,N) particles distributed in a nickel matrix. For example, in one embodiment, the coatings may be formed by sputtering pure compounds and co-sputtering of NbC and nickel. The materials to be sputtered may be, for example, in powder form.

In one embodiment, a method of forming a composition is provided, wherein the method comprises: A) providing a substrate; and B) disposing on the substrate a mixture of elements to form the composition, the mixture comprising niobium, carbon, and at least one additional element, and wherein B) may involve deposition under a condition involving a processing intensity parameter. In one embodiment, the composition may be any of the coating compositions described above. The disposing may refer to any of the deposition techniques described above, including, for example, sputtering, such as by PVD.

The substrate in the various inventive embodiments described herein may be any suitable substrate to which the coating composition may be disposed over or on. For example, the substrate may comprise a metal, an alloy, a ceramic, or combinations thereof. In one embodiment, the substrate may comprise at least one of glass, silicon, steel, hard metal, solid carbide, and a ceramic material. In some cases, the substrate may be an industrial tool that may be coated with the presently described coating compositions. The tool may comprise hard metal or solid carbide, or both.

In another embodiment, a method of forming a composition is provided, wherein the method comprises: A) sputtering, under a condition involving at least one processing intensity parameter comprising at least one of an applied bias and an applied pressure, a mixture of niobium, carbon, and at least one additional element onto a substrate so as to form the composition; and B) controlling the processing intensity parameter so as to affect at least one property of the composition. As noted above, sputtering may refer to PVD and the property may refer to any of the material properties described above, including the dependence of the property of the constituents of the coating composition.

The presently described methods may provide several unexpected advantages over the pre-existing coating fabrication technique. For example, the temperature that is needed for coating deposition described herein may be much lower than that needed in conventional coating methods to make a coating of the same material properties. For example, the disposing (e.g., sputtering) may be carried out at a temperature that is less than about 1200° C.—e.g., less than about 600° C., less than about 500° C., less than about 400° C., less than about 200° C.

The term “process intensity” is a term defined by the present inventors in the context of the presently described coating and coating methods. In one embodiment, the process intensity comprises (or is a function of) an applied (voltage) bias and a deposition pressure (pressure of gases inside the deposition chamber). In one embodiment, the process intensity may be a product of an applied bias and deposition pressure. As will be shown below, the process intensity during the fabrication process may be changed to tailor the material properties of the coating composition, including, for example, surface topography, density, and/or compressive residual stress. For example, increasing the process intensity may increase the magnitude of at least some material properties; in some alternative embodiments the magnitude of at least some material properties may be decreased by increasing the process intensity. Because the process intensity may be a function, such as a multiplication product, of multiple parameters (e.g., applied bias and applied pressure), increasing any of the parameters alone or a combination of some together (but not necessarily both) may increase the value of process intensity. For example, only the applied bias may be increased; alternatively, only the applied pressure may be increased. In another embodiment, both the applied bias and the applied pressure may be increased. Depending on the context, one of the parameters might dominate the increasing effect more than another. For example, in one illustrative embodiment, the same level of increase in hardness value may be accomplished by a 100% increase in the applied bias but only a 30% increase by the applied pressure.

Applications

The coating compositions and the methods of making the same may be applied to various applications. For example, they may be applied to industrial applications (e.g., tools used in cutting and/or forming). The tool may be any cutting tool, mold, and/or die. In one embodiment, the coating may replace the pre-existing coating material to be applied to coat, for example, an industrial tool to obtain the aforedescribed improved properties.

### NON-LIMITING WORKING EXAMPLES

### Example 1

### Niobium Carbide and Carbonitride Coatings Produced by Physical Vapor Deposition

Experimental Details

PVD films were produced by magnetron sputtering in a system from AJA International (ATC 2000 UHV). A base pressure of less than 3×10⁻⁵ Pa (2×10⁻⁷ Torr) and deposition pressures of 0.40 Pa and 0.67 Pa (3 and 5 mTorr) were employed. The system RF bias was varied between 0 and 150 V. All depositions were conducted using a 400° C. substrate temperature, as measured by a k-type thermocouple in contact with the sample holder; temperature was constant throughout the process, with variation of less than 0.5° C. Direct sputtering from a NbC target (99.5% pure) was used for all experiments, with 200 W sputtering power at 480 V. Before sputtering, samples were polished down to 1 micron with diamond media, cleaned in acetone, dried with nitrogen and plasma cleaned using 25 W and 150 V RF bias for 10 min. Due to the low deposition rate (of about 100 nm/h), the sputtering time was fixed at 5 h for each condition.

For the carbonitride coatings, the sputtering conditions are described in Table 1. Direct sputtering from a NbC target (99.5% pure) was also used for the NbCN coatings, with the N additions effected by sputtering under a N-rich atmosphere: NbC sputtering under nitrogen (0.8 Pa) and simultaneous sputtering of NbC target plus a pure (99.9%) Nb under the same nitrogen atmosphere. For the NbN, traditional reactive Nb sputtering under N was used (see Table 1 for details). The high bias experiments refer to 70 v at 0.7 Pa total pressure both NbC and NbC0.6N0.4, and 150 v at 0.4 Pa for the NbN sample. Those conditions were the ones that attained the highest hardness, without deterioration of the films. The “No Bias” condition refers to the sputtering with 0 v and 0.4 Pa. After sputtering, the thickness of all coatings was measured to be about 400 nm for all coatings, and about 700 nm for the 0 v bias NbC.

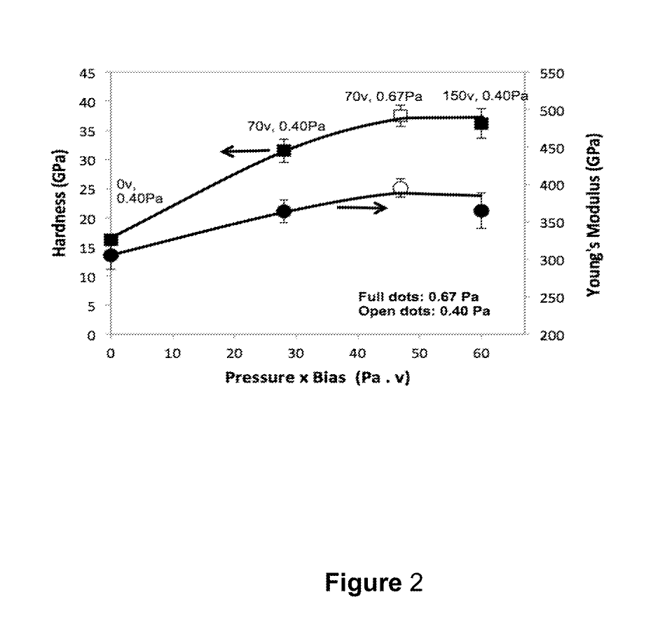

TABLE 1
Conditions of NbC₍₁₋ₓ₎Nₓ coating compositions. The error values represent the variations
obtained from the X-ray data calculated according to FIG. 2 and 20% experimental error for
the Auger Electro Spectroscopy (AES), results in terms of carbon and nitrogen contents.

| | Sputtering | | | | |
|---|---|---|---|---|---|
| | conditions | N partial | | | Bias and total |
| | (targets, power, | pressure | x calculated | x measured | pressure |
| Designation | time) | (Pa) | by XRD | by AES | “Process Intensity” |
| NbC | NbC, RF 200 w, 5 h | — | — | — | Low: 0 v, 0.40 Pa |
| | | | | | High: 70 v, 0.67 Pa |
| NbC_{0.6}N_{0.4} | NbC, RF 200 w, 3 h | 0.08 | 0.40 ± 0.05 | 0.35 ± 0.09 | Low: 0 v, 0.40 Pa |
| | | | | | High: 70 v, 0.67 Pa |
| NbC_{0.4}N_{0.6} | NbC, RF 200 w, 3 h | 0.08 | 0.62 ± 0.05 | 0.56 ± 0.10 | Low: 0 v, 0.40 Pa |
| | Nb, DC 250 w, 3 h | | | | |
| NbN | Nb, DC 250 w, 1 h | 0.06 | — | — | Low: 0 v, 0.40 Pa |
| | | | | | High: 150 v, 0.40 Pa |

The films were deposited on glass and on H13 tool steel substrates. The tool steel samples were heat treated before deposition through hardening at 1020° C. and double tempering at 600° C. for 2 h each, leading to a hardness of 45 HRC. This procedure is common for hot-worked tool steels and leads to a stable dispersion of secondary hardening carbides that only show extensive coarsening and hardness loss for temperatures beyond 550° C.

Mechanical properties were characterized by nanoindentation using a Hysitron indenter with a Berkovich tip. The same tip was used for all experiments, with an area function carefully calibrated for indentation depths between 20 and 80 nm; the error in relation to the fused silica calibration standard was below 5% in terms of hardness and modulus. These low indentation depths were used to preserve the accuracy of hardness and modulus measurements, as the thickness of the produced coatings varied between 300 and 600 nm. Therefore, indentation depths between 30 and 50 nm were used in all experiments to ensure a bulk measurement free of interference from the substrate. The indentation load was adjusted (between 600 and 3000 μN) to achieve these depths depending upon the coating hardness. The same nanoindenter was used to determine surface roughness in scanning contact-imaging mode.

Phase characterization was performed initially by X-ray diffraction (XRD) using a Rigaku H3R Cu-source Powder Diffractometer, operating at 50 kV and 200 mA with Cu Kα radiation. A scatter slit and divergence slit of 0.5° were used to concentrate the diffraction beam on the small samples (about 1 cm²) and to increase the signal/noise ratio respectively. All patterns were then analyzed using Rietveld refinement, leading to precision on lattice parameters (“a”) better than 0.005 Å. This accuracy level was obtained by the use of an external standard Si powder sample and also by the use of substrate iron peaks as an internal standard. Differences in lattice parameter (“Δa”) were used to calculate the residual elastic macro strain via Hooke's law: σ=−E·ε/(2ν), where E is the elastic modulus, ε=Δa/a₀ the residual strain calculated with respect to the lattice parameter of NbC, a₀=4.47 Å (average of powder diffraction files numbers 00-038-1364 and 01-070-8416) and ν=0.235 is the Poisson's ratio for NbC. This method was preferred to the sine-square psi traditional XRD method, due to the low intensity in high angle reflections and considerable broadening observed in many of the conditions. The method has been previously validated for coatings when the stress-free compound lattice parameter is known and the sample lattice constant is determined with high accuracy. Not to be bound by any particular theory, but the increase in lattice parameter normal to the surface (a₀ measured by XRD) is related to compressive stress. The elastic modulus used for each condition is the one measured for the actual samples, as shown in FIG. 2. In the present case, both conditions were satisfied, being the lattice constant for NbC calculated from sources of high quality with variation between then inferior to 0.0006 Å.

XRD data was used to calculate the C to N ratio in the composition in Nb(C,N). Rietveld refinement was applied to evaluate the lattice constant of each XRD diffractogram, providing an accuracy better than 0.009 Å. The iron substrate peaks were used as internal references, thus decreasing the error during Rietveld refinement. Due to this high precision, the measured lattice parameter for the intermediate Nb(C,N) compositions was used to calculate the amount of nitrogen, based on the reference patterns of highest quality for pure compounds and three indexed patterns for intermediary NbC_{0.5}N_{0.5}. Most of powder diffraction files represent NbN as a stoichiometry of NbN_{0.9}, but the 1:1 ratio was maintained. The determination of N content by the gradual change in lattice parameter was preferred to traditional spectrometric evaluations, due to the less dependence on standards and no effect from the substrate. Nevertheless, results from Auger Electron Spectroscopy (AES) were also employed, and these results were in agreement with the N content calculated by XRD (see Table 1).

The results of hardness and residual stresses were correlated to sample surface topography by analyzing the as-coated surfaces under a Zeiss field emission scanning electron microscope (SEM). Focused ion beam (FIB) was used to extract samples for transmission electron microscopy (TEM) evaluations with a JEOL 200 kV instrument. FIB preparation involved cutting samples from the coating using 1.5 nA and 30 kV conditions, initial thinning with 30 kV 80 pA to a thickness of 300 nm, slow thinning with 30 kV and 40 pA to a thickness of 150 nm, and final thinning using low acceleration conditions of 5 kV and 20 pA. The final thickness of the TEM samples was between about 60 nm and 100 nm in the imaged regions. FIB trenches were also used to determine the thickness of deposited coatings on the steel substrates.

Results

NbC Coatings

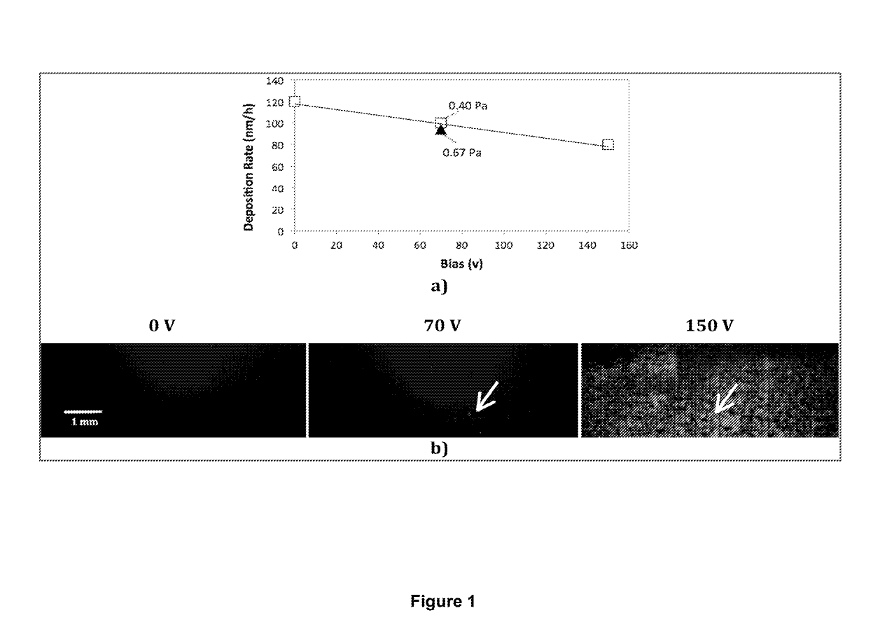

The sputtering conditions were found to affect significantly the properties and surface conditions of the sputtered coatings, as shown in the comparison of the coating thicknesses and visual surface appearances in FIG. 1. The increase in the process intensity (in this case referring specifically to bias) resulted in an apparently linear decrease of thickness (as converted to deposition rate in FIG. 1(a)), and also a loss of coating structural integrity. The damage on the deposited films was observed visually, by a clear fragmentation of the film (see FIG. 1(b)). No changes were noted with the variation of internal pressure from 0.40 to 0.67 Pa. Films deposited on glass were compared (see FIG. 1(b)); the images refer to coatings/films deposited on glass slides and analyzed by a transmission optical microscope under low magnification. The white spots (as marked by arrows) are the positions where light could go through and thus refer to less structurally sound films. This last effect was largely suppressed in the low process intensity (in this case referring specifically to low bias) bias condition (70 V) and was probably caused by localized instabilities of sputtering in this case by contrast, the effect was quite strong in the high process intensity (in this case referring to high bias) bias condition (150 V). Therefore, X-ray diffraction and nanoindentation could not be properly conducted on this 150 V bias sample, as most of the coating detached from the surface during preparation.

On the other hand, bias positively affected the hardness and Young's modulus, as shown in FIG. 2. The total deposition pressure was found also important to mechanical properties, and in fact the product of bias and pressure together represents a useful parameter to capture the “process intensity,” with increases in either of these two processing parameters generally having the same physical effects. Therefore, in FIG. 2 the x-axis convolves the pressure and bias, but the individual values of bias and pressure are also labeled next the individual experimental data points. While the 0 V bias condition rendered NbC coatings with hardness and modulus below the values expected for bulk samples (about 20 GPa and 400 GPa, respectively), a strong increase in both properties was observed with bias. The hardness values at biases above about 70 V are well above the nominal bulk NbC hardness of 20 GPa, reaching values as high as 37 GPa.

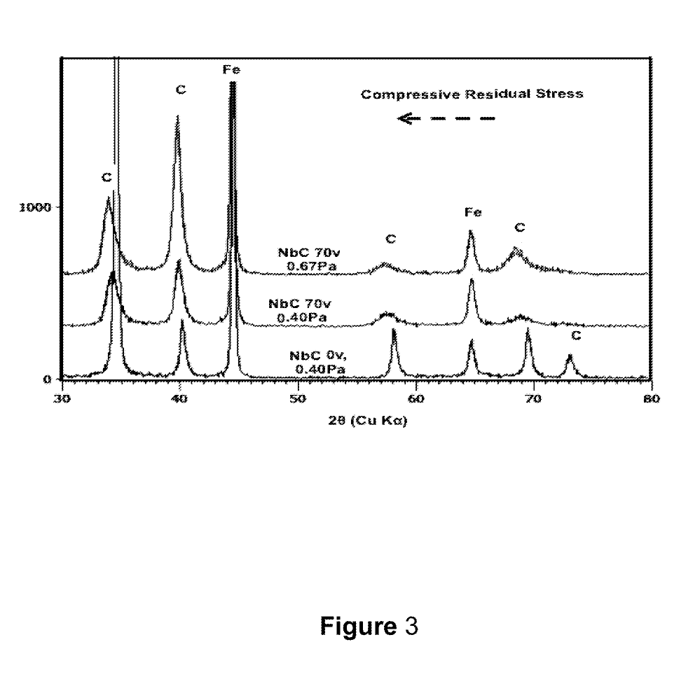

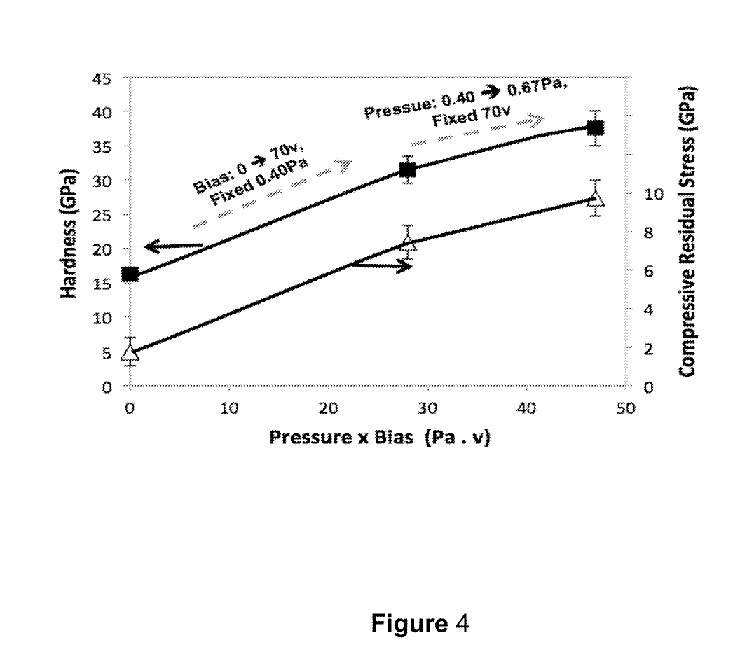

The XRD results (FIG. 3) indicate that all of the tested processing conditions led to the deposition of cubic NbC (δ phase), but with small shifts in the peak positions to smaller diffraction angles. This indicates an increase in the lattice parameter in the direction normal to the coating surface, which is related to compressive biaxial stresses in the plane. These shifts were converted to residual stress values as shown in FIG. 4. A roughly monotonic (e.g., linear) relation was observed in terms of the increase in both the hardness and residual stresses as the processing intensity is increased. It is surprising that these two mechanical measurements appear to follow identical trends with the processing parameters.

FIG. 4 shows the effects of the process intensity on the hardness and compressive residual stress. However, the data obtained thus far indicate that pressure has a significant but likely secondary influence, as compared to the applied bias. An increase in pressure results in about 20% increase in hardness but about 2 times higher hardness is obtained after changing the bias from zero to 70 V.

In addition to the macro residual stress that causes peak shifts, peak broadening was observed for samples produced with different bias conditions. By applying Rietveld refinement and the Williamson-Hall plot for the FWHM (full width at half max) data, the broadening was shown to be related only to the increase in microstrain between the condition of zero bias and high bias. The microstructure observations, as explained later, confirm this point, as no grain size change was observed among these various samples.

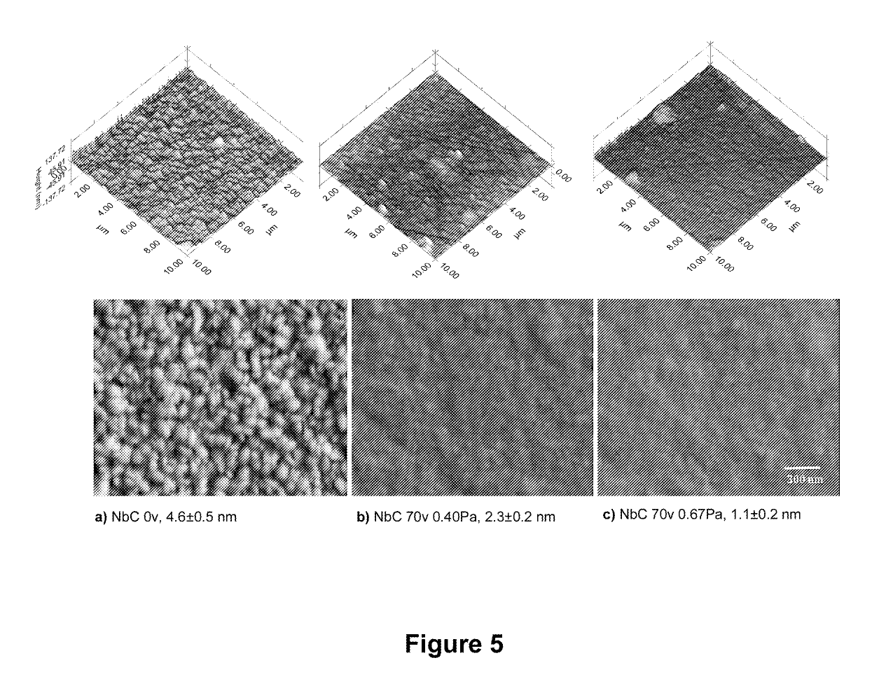

In addition to changes in hardness, modulus, and residual stress, the manufacturing conditions of the coating were found to affect the surface roughness conditions. The surface roughness appears to decrease significantly as the bias increases from zero to 70 V. This is shown in FIGS. 5(a) and (b). Further change to the surface morphology was also observed when deposition pressure (P) was increased from 0.40 to 0.67 Pa, as shown in FIGS. 5(b) and (c).

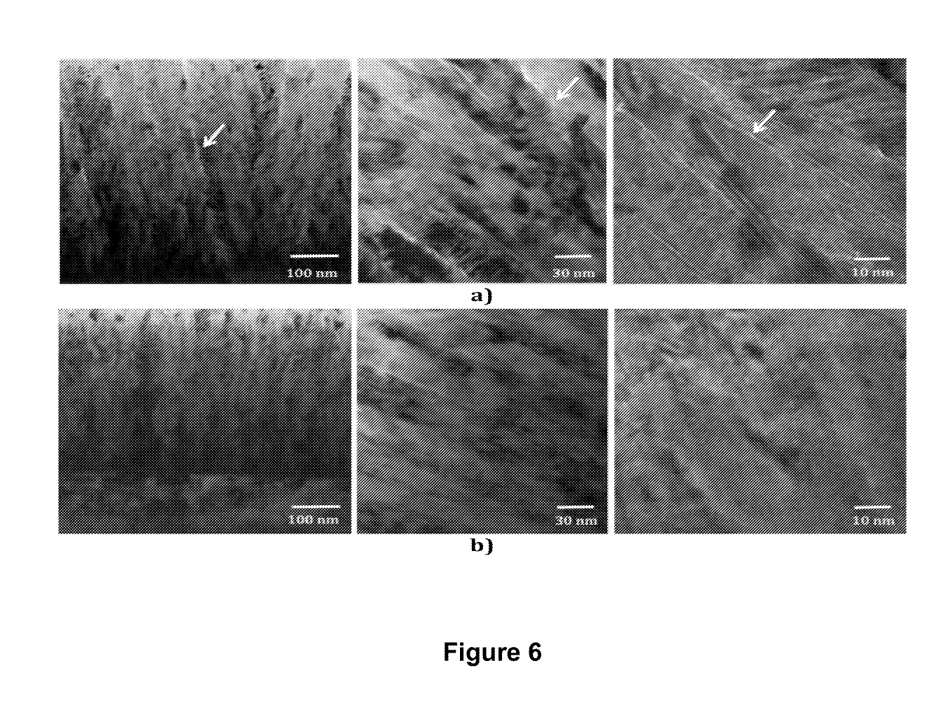

The coating microstructure is shown in the cross-sectional TEM images provide in FIG. 6. FIG. 6 echoes the aforedescribed observations that a change was observed with the application of bias. Not to be bound by any particular theory, but this change pertains to apparent porosity in the coatings.

As shown in FIG. 6(a) in the low bias condition, a very fine polycrystalline structure was observed. Several light areas were observed in practically all the film sections in the low bias sample, as shown in FIGS. 6(a) to 6(c). Another example for thicker lamella is shown in FIG. 6(b). The extensive evaluation of these samples, using dark and bright field, as well as different FIB conditions, indicate that the electron beam directly went through those areas, showing that these areas are likely small voids between the columnar grains—e.g., nanoporosity. Large areas of about 2 nm and small regions with less than 1 nm were observed, and some are pointed by arrows in FIGS. 6(a). While this small porosity was already observed in low bias TiN samples, the extent of the results in FIGS. 6(a) and 6(b) indicate that it has been observed in higher amounts in the present films.

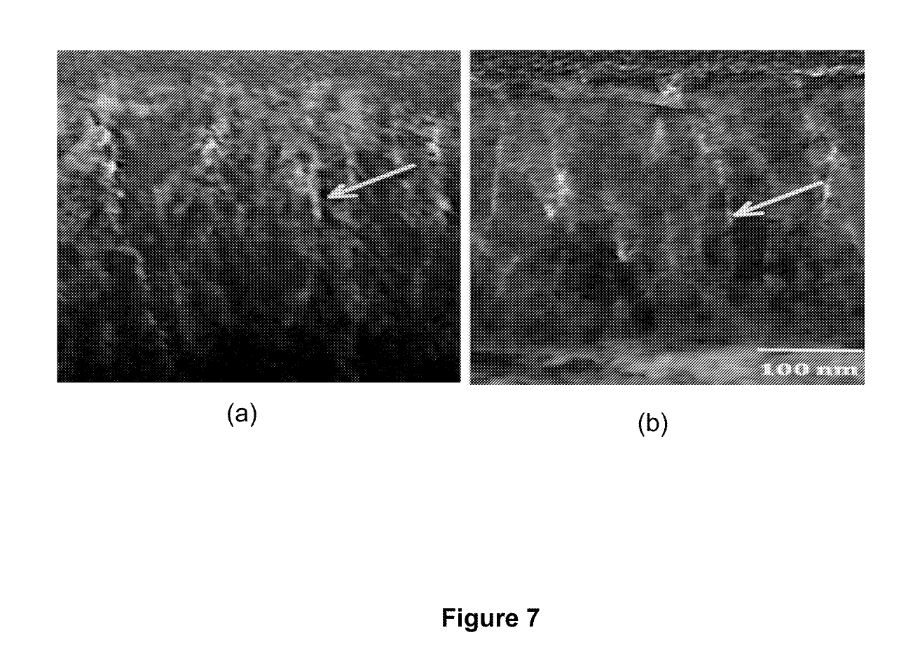

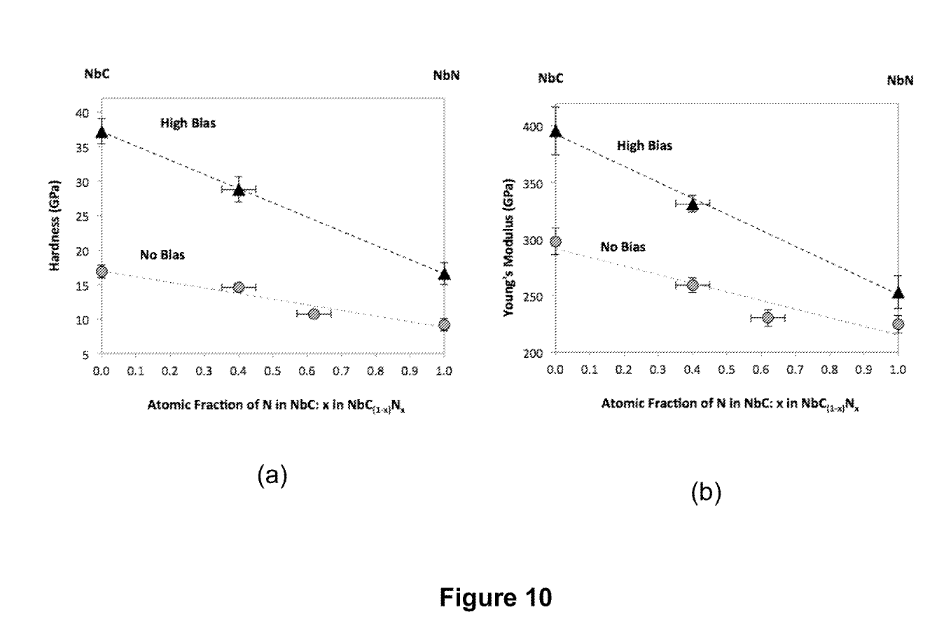

By contrast, samples prepared at high process intensity appear to have higher density than those without high process intensity (FIG. 6(b)). TEM observations on the low bias specimens containing N also show porosities in similar levels to the low-bias NbC films (see FIG. 7). The nitride and carbonitride films also exhibited the same columnar grain structure, with a characteristic grain width of about 30 nm (FIG. 10). Moreover, the light areas were not observed within the columnar structure or even between the large columns, which may indicate a reduction or elimination of the nanoporosity observed in the low bias samples. In addition, a darker matrix was noted, which may be a qualitative indicator of higher amount of microstructural defects (point defects or dislocations). The differences in thickness might affect this result, but the observation from the matrix condition was shown to be more important than possible differences in thickness. In addition, the FIB and acceleration conditions were used to promote similar conditions to both samples. In fact, the amount of this darker area in TEM echoes the XRD results that indicate an expressive increase in microstrain.

Nb(C,N) Coatings

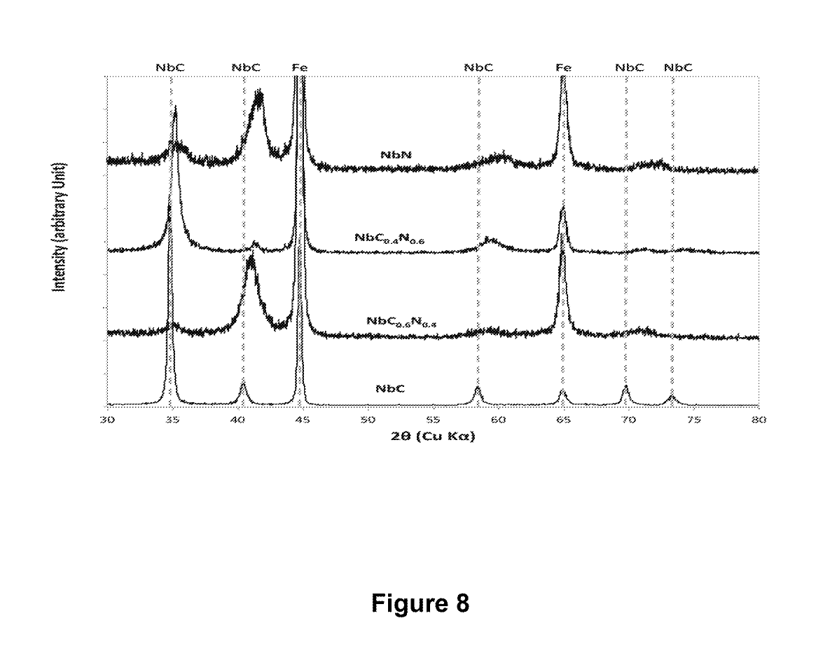

FIG. 8 presents the XRD diffractograms for the samples without bias—samples with low level of densification and low level of residual stresses, as shown in FIG. 4. In FIG. 8, only the zero volt bias samples are included in the figure; the difference in signal/noise of patterns is likely caused by the higher thickness of NbC coating as well as the difference in preferential orientation. These all show the typical pattern for the face-centered cubic phases, with the NbC and NbN peaks separated from each other by a small but important difference, and the intermediate compositions positioned between the two pure compounds as expected for solid solutions. The high bias samples exhibited some peak shift due to residual stress. The monotonic dependence of lattice constant to N content in Nb(C,N) observed in FIG. 2, in which the lattice constants as determined in FIG. 1, were marked and the referent N content calculated. The high bias samples also show face-centered patterns, but with peak shift due to residual stress.

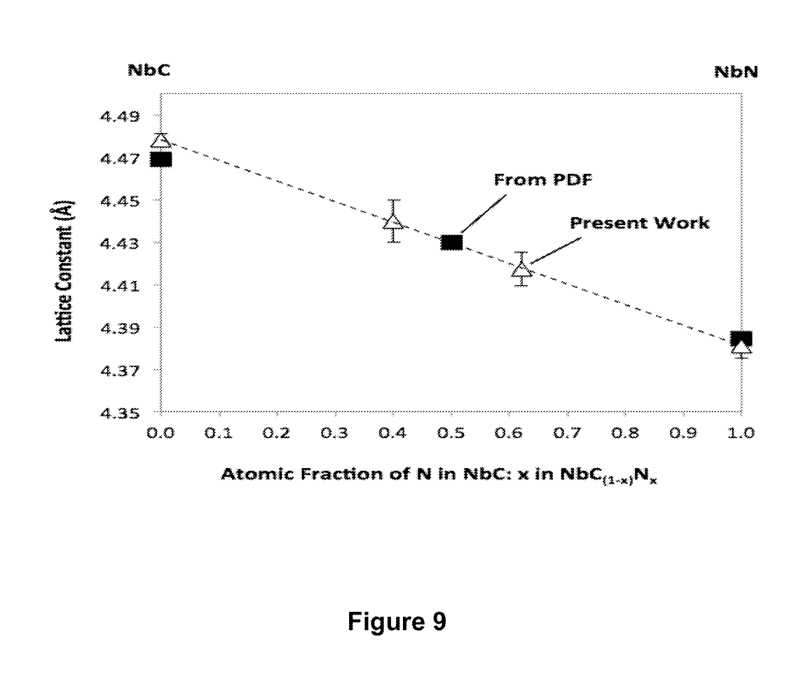

The calculated N content from the data of FIGS. 8 and 9 was then used to correlate the measured mechanical properties, as shown in FIG. 10. A monotonic dependence (e.g., linear in this case) was observed for all sample compositions when hardness and elastic modulus were plotted as a function of the nitrogen content—and this was also seen in the high bias conditions. Thus, the design of coatings with different levels of hardness may be accomplished by adjusting the nitrogen content in the NbC coatings.

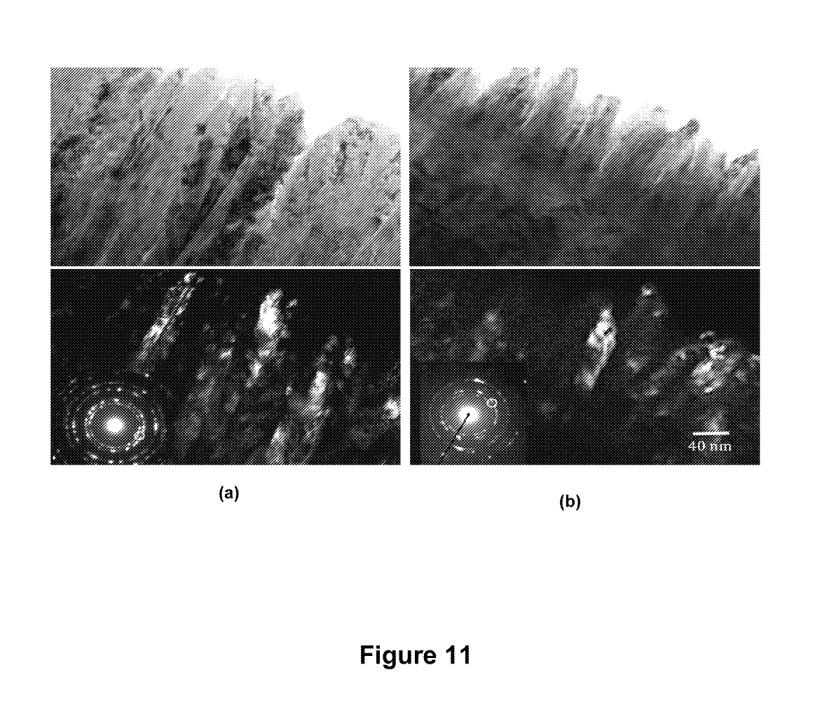

Another possible way to control the coating hardness is to change the bias and sputtering variables, as shown in FIG. 2. However, the change in bias led to lower hardness by deteriorating the film microstructure (as discussed and shown in FIG. 6), and thus it is not desirable. On the other hand, by changing the N content, the integrity of the film may be preserved and the reduction in hardness thus may be solely related to the partial substitution of C by N. This is especially relevant considering similarities in the grain sizes, as shown in the comparison of NbC and Nb(C,N) microstructures (FIG. 11). No significant change in columnar grain structure was observed, and the width of the grain was found to be about 30 nm.

Discussion

Process Variables and Properties of NbC Coatings

The results show that NbC coatings made with PVD have hardness at the same level or even slightly higher than pre-existing PVD coatings. More specifically, with hardness values up to 37 GPa, the coatings are reasonably matched to generally known TiN (23 GPa), (Ti,Al)N (30 GPa), and CrN (23 GPa). It was found that the mechanical property values were dependent upon processing conditions, such as the bias or deposition pressure. For example, an increase in bias may result in an increase in compressive residual stress.

This effect of bias is known to affect densification and the compressive residual stresses in some coatings. In fact, similar trends have been reported for NbC coatings produced by other techniques, such as arc evaporation. Similar trend is also observed in TiN films produced by PVD or CrN. In the present case, the increase in mechanical properties may be attributed to the reduction or minimization of high level of visible porosity in these films. The decrease in this ratio led to films of Type I morphology, which is porous and has low mechanical properties.

The sensitivity of NbC to this effect is significantly higher than nitrides (e.g., TiN or CrN) due to the higher melting point of NbC (about 3800 K and 3200 K for TiN and 1800 K for CrN). Therefore, for the same substrate temperature (400° C. in this experiment), NbC coatings would be more prone to accumulate porosity under non-optimized sputtering condition. On the other hand, other denser morphologies (e.g., Type II or Type III as defined by Thornton) may be produced under higher Ts/Tm ratios. However, because Tm is fixed for a given compound, it may be very difficult to increase substrate temperature Ts in many instances because several substrates are not possible to be heated above e.g. 500° C. Thus, when the substrate is, for example, a tool steel substrate (which cannot be heated to above 500° C. because of its tempering temperature during coating process), it is difficult to achieve densification by relying on the aforedescribed heating technique.

The process involving process intensity may overcome the aforementioned challenge. Specifically, changing the process intensity allows tailoring of the level or densification in the coating produced. As shown in FIGS. 2 and 6, hardness, as well as the elastic modulus, increased after the reduction of porosity, for films produced with higher process intensity.

On the other hand, upon minimizing the porosity by increasing the bias, as shown in FIG. 6, both the hardness and elastic modulus were found to increase to values consistent with expectations for the bulk compound (FIG. 2). This change in properties was also accompanied by a continuous increase in residual stress, which seems to achieve levels higher than are common for nitrides. Nevertheless, the comparison of residual stress between NbC and TiN or other coatings was less direct than the comparison of hardness, due to the difference in elastic moduli; the modulus of NbC is higher by a factor of almost two than that of TiN. In other words, at the same strain level the residual stress in NbC was inflated by the same factor. The coatings may best be compared on the basis of residual strain. Literature results for TiN coatings show stresses between 3 to 8 GPa for bias of about 70 to 100 volts, which relates to strain between 1.0 to 2.0%. And this strain level is similar to the determined strain for NbC coatings of the present paper, about 1.0% for 70 V bias.

There were many reasons for this observed increase in compressive residual elastic strain (and thus residual stress) upon increasing the process intensity, two of which are considered important: i) thermal effects related to the different thermal expansion between substrate and coating, and ii) the introduction of strain during sputtering. All these effects cause an increase in densification, and thus are consistent with the observed increase in residual stresses.

On the other hand, the highest bias conditions, especially 150 V, used in this Example resulted in a deposited film that was not structurally sound and was almost fully delaminated from the surface. Extreme values of compressive stresses (e.g., about 10 GPa) are expected for such conditions; thus, these are likely the main limitation against continuously increasing the applied bias. For example, the literature shows that residual stresses over 7 GPa in TiN tend to cause deterioration of the produced film.

Many reports show that for other compounds, the change in bias is related to the stronger acceleration of the positive atoms against the substrate, leading to stronger (thus denser) film. The effect of internal pressure particularly relative to direct sputtering as described herein, has not been examined. Not to be bound by any theory, but it is possible that the internal pressure changes the average amount of positive atoms (in this case C⁺) reaching the target because of the smaller size relative to the metal atoms (Nb). Thus, the relation between the flux of ions (Ji) and metal (Ja) would then be changed. This parameter is important to coatings properties because stronger atomic shock arises when the relation Ji/Ja increases. This results in better densification and higher hardness. Alternatively, the higher internal pressure may increase the number of shocking atoms on the as-deposited films, thereby increasing the densification in a similar way to the increase in speed of shocking atoms (bias effect).

The surface roughness of the coating was found to be affected by the PVD processing conditions (see FIG. 5). Not to be bound by any particular theory, but the higher degree of smoothness on the surface of high bias samples could be explained by a constant “plasma cleaning” during the deposition process by Ar⁺ ions accelerated against the surface. This roughness would likely be affected by both bias and internal pressure, as these two parameters would control respectively the speed and number of shocking atoms.

Therefore, the effects of bias and change in internal pressure seem consistent with the same mechanisms proposed for traditional PVD coatings. Some of these effects are stronger for NbC than for other compounds due to the lower homologous processing temperature Ts/Tm, which in turn is caused by the high melting point of NbC.

Effect of Nitrogen in NbC PVD Coatings

As shown in FIGS. 8 to 10, the different structure and mechanical properties were found to vary monotonically as N-addition (as substitution for C) was added in NbC. Not to be bound by any particular theory, but the differences of hardness in the intermediate compositions of the system NbC₍₁₋ₓ₎Nₓ could be attributed to the partial substitution of Nb—C bondings to Nb—N bonds, which may lead to a lower hardness, as compared to the bulk hardness of NbC (about 24 GPa) and NbN (about 14 GPa) compounds. Nevertheless, the hardness of the NbC_{0.6}N_{0.4} is still of about 28 GPa, which is comparable to conventional TiN coatings.

Therefore, the findings show that N additions may be used to control the hardness of NbC direct sputtered PVD coatings. In fact, controlling the amount of N added was found to be a better way to control hardness than changing the deposition variables related to bias. This ability to control may be important to applications where high toughness is desirable, such as those with failure mechanism related to coating chipping or spalling.

Conclusions

The microstructure, properties, and surface hardness of NbC coatings were shown to be dependent on bias, to a larger extent than that observed for TiN or CrN. The bias effect was found to affect nanoporosity, thereby affecting the mechanical properties. The nanoporosity was found to be considerably higher in the samples sputtered under zero bias, but very minimal for samples sputtered under high bias.

The densification by the increase in bias follows the traditional models for bias effect, as a result of the higher acceleration of ions during the deposition process. The higher sensitivity of NbC to this effect was related to the higher melting temperature, in relation to nitrides, thus reducing the ratio between the absolute substrate and melting temperature (Ts/Tm) and causing a high sensitivity for porosities under low bias conditions.

Very high values of bias (e.g., 50 V) were found to cause the deterioration of the coating film and could not be applied to produce a film with sound structural integrity, possibly due to the high levels of compressive stresses developed under the highest bias conditions. Using optimized sputtering conditions, NbC hard coatings with dense microstructures were produced. The coatings were found to have hardness values higher than those of conventional nitrides, such as TiN films.

To produce films with hardness and physical properties closer to traditional TiN films, modification with the addition of N into NbC may be applied. The resultant carbonitride coatings showed a cubic structure but monotonic dependence of lattice and materials properties on N content (as a substitute for C).

### Example 2

### Nanocomposite PVD Coatings Based on Niobium Carbide and Nickel

Experimental Details

PVD films were produced by magnetron sputtering, in a system from AJA International (ATC 2000 UHV). The base pressure of less then 3×10⁻⁵ Pa (2×10⁻⁷ Torr) and two deposition pressures were applied: 0.40 Pa and 0.67 Pa (3 and 5 mTorr). System RF bias was varied between 0 and 70 V. All depositions were done at 400° C. substrate temperature, measured by a k-type thermocouple in contact with the sample holder. The temperature was constant all during the process, with variations less than 0.5° C. Before sputtering, samples were polished down to 1 micron, cleaned in acetone, dried with nitrogen and plasma cleaned using 25 W and 150 V RF bias for 10 min.

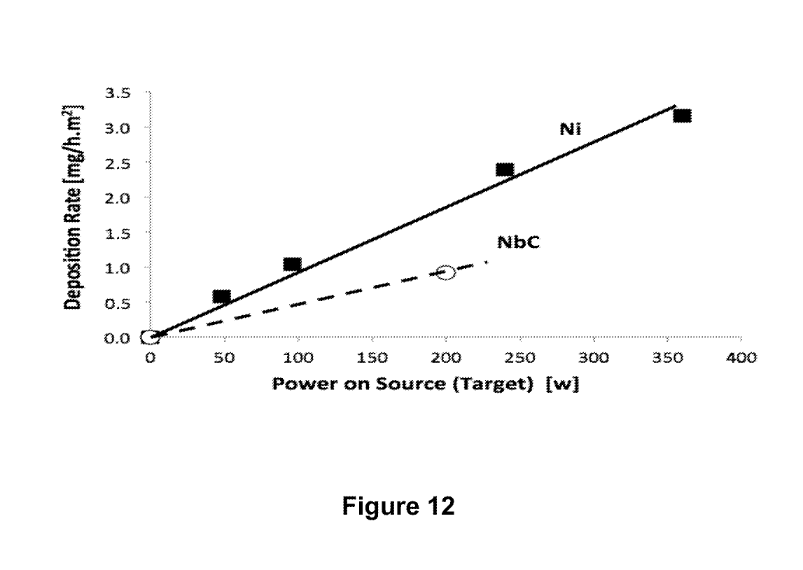

Direct sputtering of an NbC carbide target (99.5% pure) was used for all experiments, with 200 W sputtering power and 480 V voltage. Nickel additions were performed by co-sputtering a Ni target (99.9% pure). The amount of nickel was calculated by the previously determined sputtering rate of individual compounds (NbC and Ni), as shown in FIG. 12. Other details on the sputtering conditions of each sample are presented in Table 2. Due to the low deposition rate (of about 100 nm/h), the sputtering time was between 3 h and 5 h for each condition, aiming at a coating thickness of about 500 nm. The final composition was also determined by Auger electron spectroscopy (AES), as shown in Table 2. For the Auger results, carbon sensitivity was adjusted using a reference sample of pure NbC.

TABLE 2
Sputtering conditions for the compositions of NbC with amount of Ni added. The
atomic concentration by deposition rate was based on the results of FIG. 12.

| | | | Ni (at %) ^{a)} | | |
|---|---|---|---|---|---|
| | NbC Sputtering | Ni Sputtering | Calculated | Composition | |
| | conditions | conditions | by | (at %) ^{b)} | |
| | (targets, power, | (targets, | deposition | Measured by | Bias and total |
| Designation | time) | power, time) | rate | AES | pressure |
| NbC | NbC, RF 196 w, | — | — | 51% C, 49% Nb ^{c)} | Low: 0 v, 0.40 Pa |
| | 5 h | | | | High: 70 v, 0.67 Pa |
| NbC + 10 Ni | NbC, RF 198 w, | Ni, DC 15 w, 4 h | 11% | 46% C, 41% Nb, | High: 70 v, 0.67 Pa |
| | 4 h | | | 9% Ni | |
| NbC + 30 Ni | NbC, RF 200 w, | Nb, DC 48 w, 3 h | 30% | 30% C, 39% Nb, | Low: 0 v, 0.40 Pa |
| | 3 h | | | 31% Ni ^{c)} | High: 70 v, 0.67 Pa |

^{a)} The measured atomic percentage of Ni, if pure Ni phase was considered, would correspond to volume fraction of Ni of 30 vol % and 11 vol %, which is usually the amount observed in solid-carbide tools, between 10 and 30 vol %.
^{b)} Values for average of 10 measurements. Experimental error is about 15% of measured values.
^{c)} Variations in chemical composition between high and low bias was within the error of measurements.

The films were deposited on oriented silicon wafers and on H13 tool steel substrates. The properties were determined on the coated tool steel samples. The X-ray diffraction results were obtained from both samples because the Ni (111) peak was coincident with substrate Fe (110) peak and could not be observed in the steel coated/deposited samples. The tool steel samples were heat treated before deposition, through hardening at 1020° C. and double tempering at 600° C. for 2 h each, leading to a hardness of 45 HRC. This temperature procedure is common for hot work tool steels and leads to a stable dispersion of secondary hardening carbides, which only show expressive coarsening and a decrease in hardness for temperatures beyond 550° C. Thus, the constant hardness was observed on steel substrates after the long sputtering runs.

Mechanical properties were characterized by nanoindentation with a Hysitron indenter with a 10 mN maximum load and a Berkovich tip. The same tip was used for all experiments with the area function carefully calibrated to indentation depths between 20 and 80 nm. The error (in terms of hardness and modulus) in relation to fused silica sample was less than 5%, of the standard samples—within the normal variation specified by the standard sample manufacturer. Such low indentation depths were used to preserve the accuracy of hardness and modulus measurements, as the thickness of the produced coatings varied between 300 and 600 nm. Therefore, indentation depths between 30 and 50 nm were used in all experiments, preserving a factor of 10 relation between coating thickness and indentation depths. The indentation load was then adjusted (between 600 μN to 3000 μN) according to coating hardness. The same nanoindenter was used to determine surface roughness.

Phase characterization was performed initially by X-ray diffraction (XRD). The obtained results were compared to the electron-diffraction patterns obtained by transmission electron microscopy. A Rigaku H3R Cu-source Powder Diffractometer was employed, operating under 50 kV and 200 mA. The goniometer of this instrument was a 185 mm radius horizontal-circle with a diffracted-beam graphite monochromator and scintillation detector. The monochromator reduced the effects from iron fluorescence under Cu Kα radiation. Scatter slit and divergence slit of 0.5° were used to concentrate the diffraction beam on the small samples (about 1 cm²) and to increase the signal/noise ratio respectively.

The results of hardness and elastic modulus were correlated to microstructural observations by analyzing transmission electron microscopy (TEM) samples extracted by focus ion beam (FIB). FIB preparation involved cutting samples from the coating using 1.5 nA and 30 k conditions: initial thinning with 30 kV 80 pA until 300 nm, slow thinning with 30 kV 40 pA until 150 nm, and final thinning using low acceleration conditions of 5 kV 20 pA. The thickness of the produced samples was about 60 nm in the top areas, increasing to about 100 nm downwards to the areas about 500 nm deeper. The last step during FIB preparation was employed to avoid heterogeneous thinning, as well as to introduce less amount of microstructural damage by the Ga⁺ beam. This was especially important in the present experiment, as one of the phases could be easily amorphized. FIB trenches were also used to determine the thickness of deposited coatings on the steel substrates. After thinning, the prepared samples were analyzed by TEM using a Jeol 2011, 200 kV instrument.

Results

As shown in Table 2, the ratio 1:1 of Nb and C was maintained among all compositions, but not for the specimens with 30% Ni. An extra amount of Nb was observed in this sample, even considering the high range of the experimental error. Therefore, it is possible to conclude that the high Ni-content coating part of Nb may not form NbC carbide, and instead separates from carbon. Considering the NbC stoichiometry, the amount of free Nb would be about 9 at %.

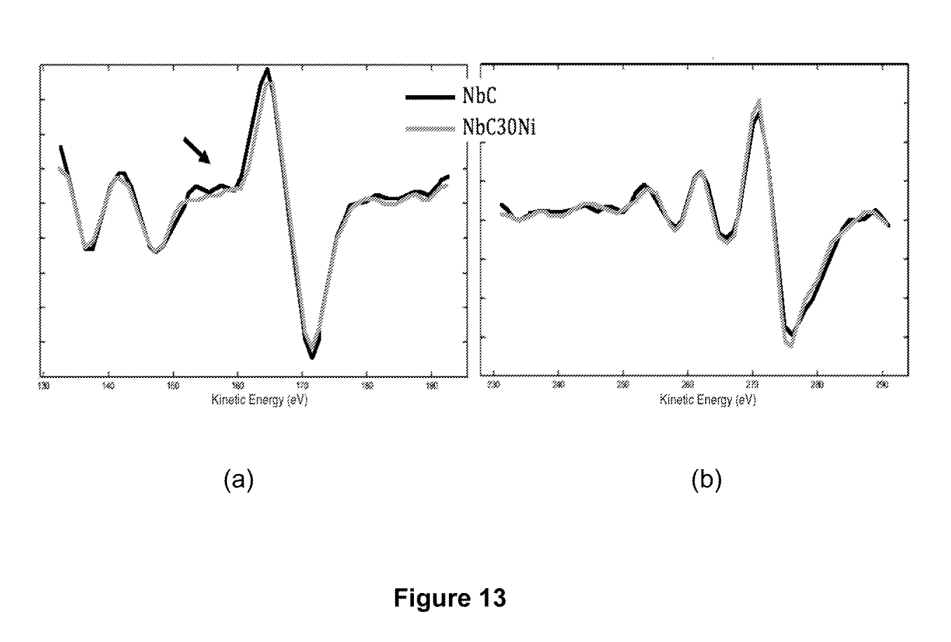

The modification in niobium bonding for the 30% Ni coating is thus expected to change the environment of the external electrons to be observed by Auger electron spectroscopy (“AES”). In fact, a comparison of the AES results for zero and high Ni coatings (FIG. 13) show a slight but visible difference between the shape of auger electrons from Nb, and coincident curves for C. This indicates that in both samples the bonding state of carbon atoms is unchanged, but Nb bonding has been modified. The AES curves echo the observations on the chemical compositions of the different coatings, showing that part of Nb is not bonded to carbon.

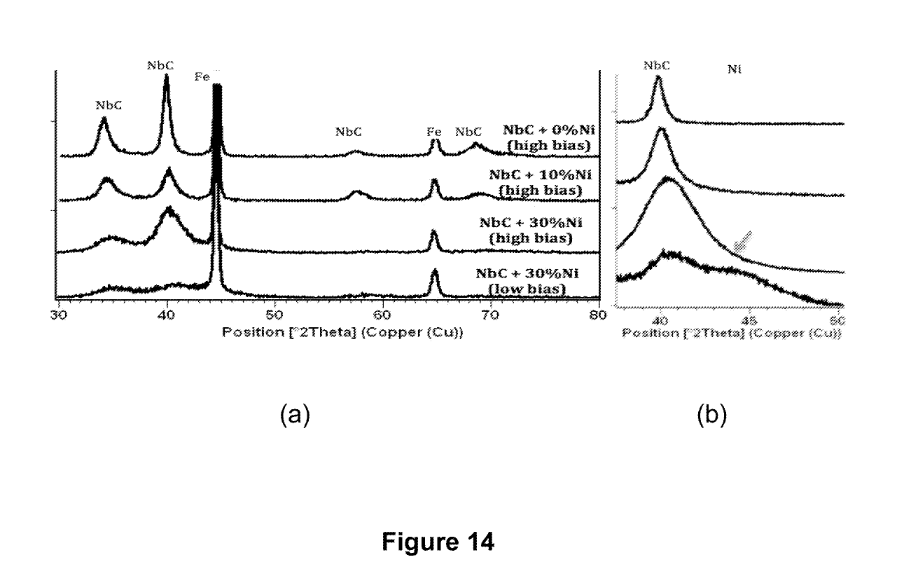

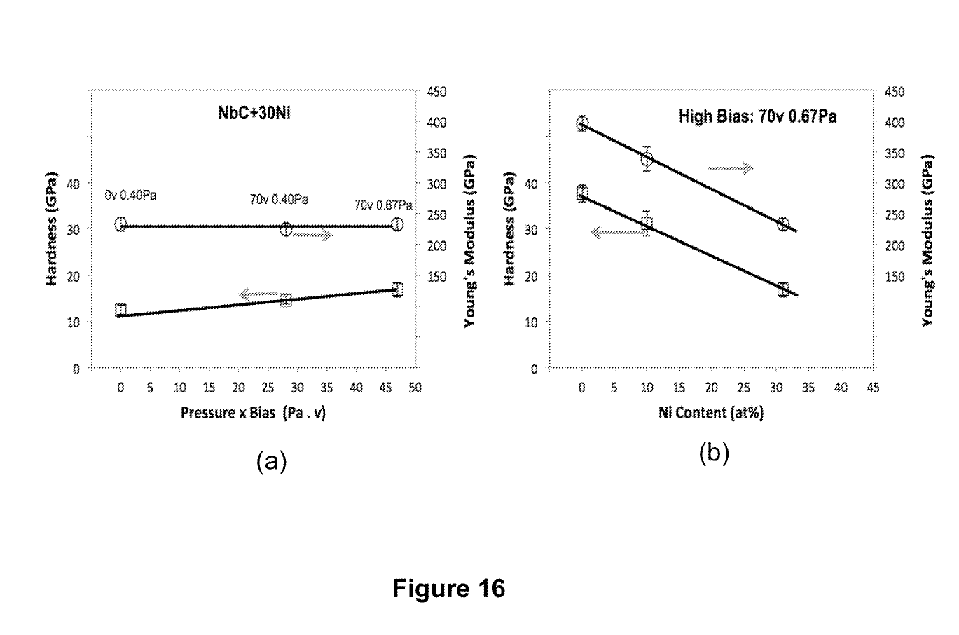

All test compositions were evaluated by X-ray diffraction, and the results are shown in FIG. 14. On the steel coated samples, only an NbC cubic phase was observed for all coatings evaluated here. Changes in peak heights due to preferential orientation were observed within the different compositions, but the strongest change in the X-ray diffraction results are related to peak broadening. The increase in Ni amount, especially under low bias, was observed to cause strong broadening in the diffraction patterns (FIG. 14(a)). This is related to either residual strain or grain refinement, and the evaluation of peak broadening versus reflection angle (Scherrer method) showed that this was due to grain refinement. The grain size was calculated to be between 2 and 3 nm for the coatings with 30 at % Ni and about 15 nm for the 10 at % Ni coating. As for the pure NbC carbide coating, the peak broadening was rather small and the crystalline grain size is larger than 50 nm. See FIG. 16.

Another important result is shown in FIG. 14(b) for coatings sputtered on silicon wafer substrates—without the Fe reflection at about 44.5°. This position is close to the strongest reflection for the Ni phase, and a broad but visible peak was observed at this angle for the NbC+30Ni sample with zero bias. This indicates that the co-sputtering of Ni and NbC formed two different phases—i.e., the carbide and another phase probably rich in Ni. No other phases were observed, and thus the free Nb could be dissolved in this new phase formed in samples rich in Ni.

The application of bias tended to increase even more the peak width at about 40°, which may be a result from further refining or stresses. Results from Example 1, on the other hand, show that the amount of residual stresses for pure NbC increases considerably after the bias application, while the other NbC reflections are shown not to be broader for the high bias coatings in relation to the low bias. Not to be bound by any particular theory, but the broadening and decreasing in intensity with bias application may be attributed to stresses emerged with bias. On the other hand, the broadening effect in high Ni high bias samples is more complex, and the following analysis concerns the low bias coatings.

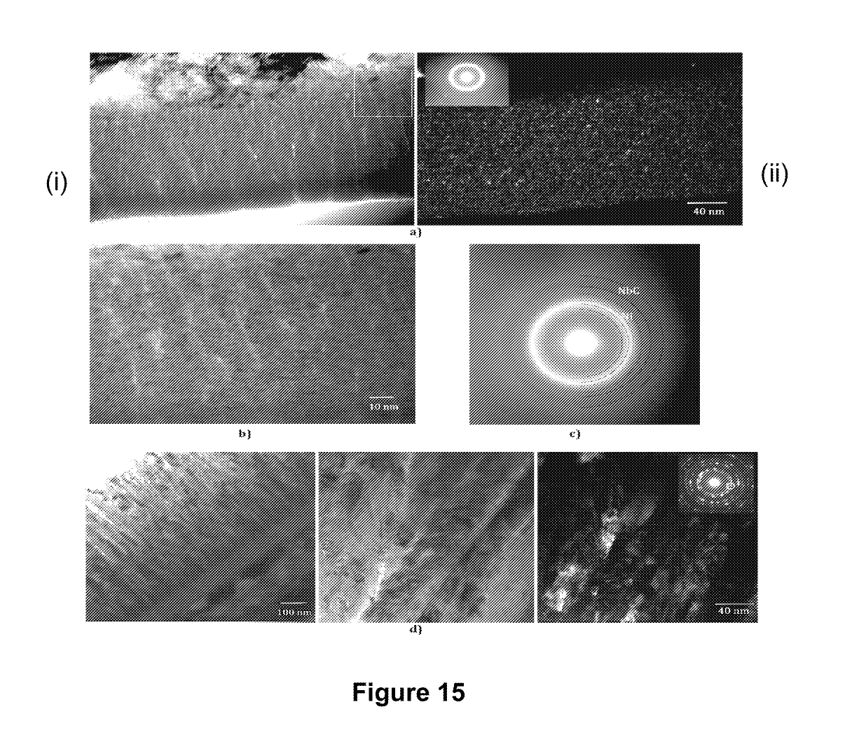

The evaluation of the grain refinement by X-ray diffraction was performed by microstructure observation on samples extracted by FIB and analyzed by TEM, as shown in FIG. 15. Grain refinement was observed, especially when comparing the dark field images in FIG. 15(a). In FIG. 15(b), a zoom-in view of this microstructure was observed, showing very small grains (about 2 nm), consistent with the size determined by XRD. The diffraction pattern from this sample (FIG. 15(c)) was also similar to the results of XRD, showing a first broad ring of NbC and a mixture of broad reflections of NbC and Ni. A third reflection from NbC is also visible, but very weak. All these characteristics were different from those of the pure NbC (FIG. 15(d)), which shows long columnar grains of more than 100 nm and clear diffraction spots (using the same diffraction aperture of 200 nm).

In addition to the changes in the sample microstructures, the effect of Ni on the mechanical properties was evaluated and shown in FIG. 16 as a function of the bias and nickel content. With respect to the bias, a small effect was observed in FIG. 15(a). Specifically, the effect was very different from the strong increase in hardness (up to 2 times) observed in pure NbC; see Example 1 above. The hardness was not found to vary significantly (<30%), and no visible change in elastic modulus was observed. With respect to the effect of Ni on hardness, high bias samples were compared (FIG. 16(b)). The Ni addition promoted a continuous decrease in hardness, which is coherent to the formation of Ni phase in detriment of NbC. On the other hand, the addition of different amounts of Ni shows that it is possible to increase hardness at high levels. For instance, 10% Ni led to about 30 GPa of hardness, which is much higher than the values reported for conventional TiN.

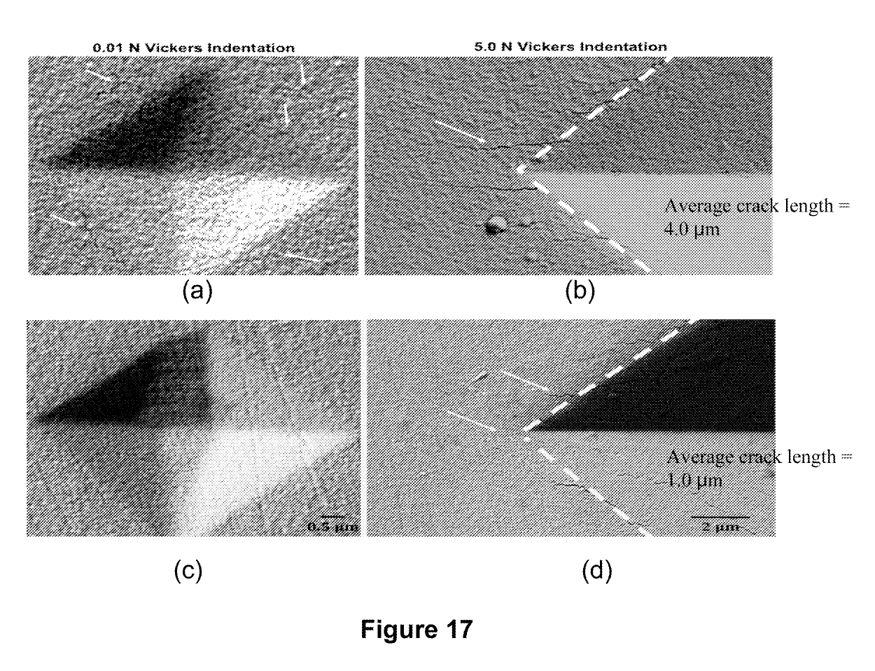

This continuous change in hardness by Ni is important to adjust the toughness and strength for a given application. Therefore, low hardness may be obtained by adding a larger amount of nickel that, by forming a metallic phase, tends to increase the coating ductility and toughness. To evaluate this, low bias samples were analyzed by observing the cracks formed after microindentation with loads: 0.01 N and 5 N, as shown in FIG. 17. For the smallest load, NbC shows many cracks close to the indent mark, while no cracks were observed in the NbC+30 sample. As for the high load indent mark, many cracks emerging from the indent edge were observed in the pure NbC, while fewer cracks with shorter lengths were found in the NbC+30Ni sample. Length and number of cracks has been related to the toughness of thin films. Because the stress state on the edges of both samples was considered the same, a qualitative valid comparison in terms of the toughness of these different coatings was provided. Edge cracks were not observed in high bias coatings, and thus the same analysis was not performed. However, it was observed that the number of cracks inside the indent mark was also reduced with the increase of Ni content.

Discussion

Two main modifications were observed after the addition of nickel to NbC PVD coatings: 1) the formation of a second soft phase and 2) the refinement caused by phase separation.

Nickel Effect on Second Phase Formation

Results from chemical composition (Table 2), AES peak shape (FIG. 13), and XRD (FIG. 14) indicate that a second phase was formed with the addition of Ni. This is shown by the X-ray peak that is close to the (111) Ni peak but broad and slightly dislocated to lower angles. Part of the Nb was also shown to be dissolved in this phase (i.e., “free Nb”) for not being bonded to carbon in the carbide phase. This excess of Nb would then be in solid solution in the second nickel-rich phase. In fact, Ni—Nb alloys do not present large amount of Nb solid solution in the Nickel rich corner of equilibrium diagram, but are well known to form amorphous alloys—e.g., the first amorphous metallic alloy ever produced by mechanical alloying was based solely on Nb and Ni, using 40% Nb. Later results showed that amorphous alloys based on NiNb show continuous dislocation to lower diffraction angles, indicating a continuous variation of the amorphous band from about 44° (20 angle for Cu Kα) for the Nb₂₀Ni₈₀ alloy to about 38° for the Nb₈₀Ni₂₀. The broad and dislocated peak of Ni (111) reflection is then possibly related to an amorphous Ni—Nb alloy. Nevertheless, in the case of a crystalline solid solution, the addition of Nb would also lead to a dislocation of XRD peaks to smaller angles (meaning larger lattice spacing), due to the larger atomic radius of Nb in relation to Ni.

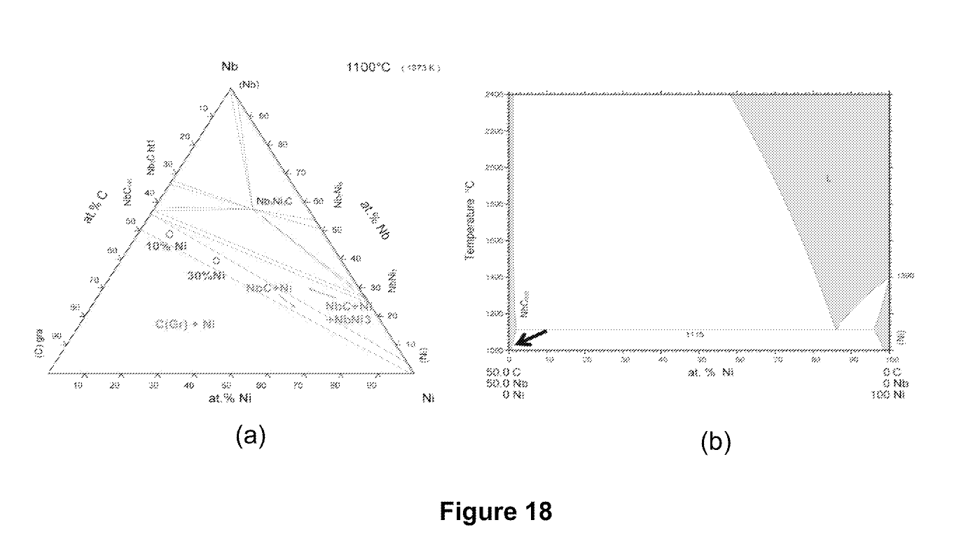

The second phase was found to be a metallic phase based on Ni, and very likely to be in solid solution with Nb. The metallic nature of this new phase is reflected in the very low tendency of Ni to form carbides in relation to Nb, as may be observed in the phase diagrams of FIG. 18. This metallic nature is also reflected in the low increase in hardness with the change in bias, for the NbC+30Ni composition. As shown in Example 1 above, the increase in bias led to an increase in residual stresses and an increase in hardness of NbC from 16 to 35 GPa may be a result of residual stress of about 8 GPa. Under such a high level of residual stresses, any metallic phase would present deformation such that the effect of bias on the final properties would become small. See FIG. 16(a). In line with this observation is toughness as shown in FIG. 17.

This new metallic phase, and likely also in solid solution, is rich in Ni. The phase led to a NbC coating with a structure similar to solid carbides (also known as hard-metals) used for cutting tools. Similar to a prior approach, a metallic (binding) phase is also present within the hard particles of carbides, and thus the amount of the soft phase is used to control the hardness and toughness of the final tool. One distinguishing feature of the present approach is that the metallic phase in the present approach is in a nanometered size and produced by sputtering. In fact, the results in FIG. 16(b) demonstrate that the Ni content could be adjusted to increase or decrease the hardness—this may be tailored to improve the toughness of the material.

No reports have been found using the presently described approach to utilize the net effect of adding a metallic phase to a PVD coating and further refining the grain of the hard phase. The adjustments in hardness and toughness by Ni addition are important because such adjustments are difficult to apply by PVD process conditions. In fact, Example 1 shows that the reduction of bias and internal pressure may decrease the hardness of NbC, but at the expense of decreasing the coating densification (or increasing nanoporosity), thereby decreasing the level of compressive residual stresses. This is undesirable with respect to striving for a balance of strength and toughness.

The addition of Ni or other metals able to form a second softer phase was desired in the finally produced composite. In this respect, the solubility of the second element should be low in the carbide—i.e., low tendency to carbide formation. Nickel and niobium carbide are suitable candidates, as shown by the previously discussed results and by data of FIG. 18.

Grain Refinement by Phase Separation

A second result from the addition of nickel, as shown in FIG. 15, is the grain refinement of the NbC grains. With 30 at % Ni addition, the NbC columnar structure was changed and broken into small grains of about 3 nm size. Different degrees of refinement were observed for the 10% Ni, but still the emerged second phase was shown to produce a refinement in the hard phase.

This effect of composite formation was studied as an attempt to increase the hardness by grain refinement (Hall-Petch effect). Not to be bound by any particular theory, but the mechanism could be related to a low solubility of the second added element to the main growing phase, causing its separation into a new phase that then grew in competition to the main hard coating phase. In TiN, both B and Si have shown this effect, by forming a new phase of TiB₂ or TiSiₓ. Even previous results on (Ti,Al)N show that, under certain bias condition, wurtzite phase is formed with a grain size of about 3 nm, but with volume fraction lower than 5%. However, this study is the first to show that the effect of a second phase based on a metallic phase causing the same refinement.

Not to be bound by any particular theory, but nickel could have caused this refinement for two reasons. First, the compositions were designed to be within the area of the ternary diagram where the hard phase (NbC) is in equilibrium with the metallic phase (Ni), as marked on FIG. 18(a). This line is drawn assuming that the NbC and Ni targets were sputtered simultaneously and the ability of carbide formation by the sputtered NbC is under the same sputtering conditions as those previously shown in Example 1.

Based on FIG. 18(b), the low solubility of Ni in NbC is less than 1 at % at the temperature used. Thus, the first option for the nickel atoms in the mixture of NbC and Ni would be to be incorporated into the newly formed NbC compound. However, the low solubility of Ni in this compound would cause a separation of Ni atoms to a new phase, which would naturally grow near the growth front of NbC. This “competition mechanism” would then lead to the small grains observed for the NbC phase after Ni addition.

### CONCLUSIONS

This addition of Nickel to NbC coatings by co-sputtering techniques was shown to produce an intense refinement of NbC phase. The grain size observed in the NbC+30Ni was about 3 nm. The mechanism for grain refinement was associated with the formation and presence of a second Ni-rich phase, also likely in solution with Nb. This second phase was found to cause an increase the toughness and to reduce the hardness, and the change was found to depend on the amount of Ni added. For example, hardness of about 17 GPa was obtained for the 30 at % Ni and 30 GPa for the 10% Ni compositions, the latter being comparable to that of conventional PVD coatings.

The articles “a” and “an” are used herein to refer to one or to more than one (i.e., to at least one) of the grammatical object of the article. By way of example, “a polymer resin” means one polymer resin or more than one polymer resin. Any ranges cited herein are inclusive. The terms “approximately”, “substantially”, and “about” used throughout this Specification are used interchangeably to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

What is claimed:

1. A coating composition, comprising:
a first compound comprising a niobium element, a carbon element, and at least one non-metal element that is capable of forming a second compound with the niobium element or a combination of the niobium element and the carbon element.

2. The coating composition of claim 1, wherein the first compound is comprises niobium carbide.

3. The coating composition of claim 1, wherein the non-metal element is a nitrogen element.

4. The coating composition of claim 1, wherein the second compound comprises a niobium carbonitride.

5. The coating composition of claim 1, wherein the second compound comprises NbC_{0.6}N_{0.4} or NbC_{0.4}N_{0.6}.

6. The composition of claim 1, wherein the composition consists essentially of the first compound.

7. The coating composition of claim 1, wherein a ratio of the niobium element to the carbon element is approximately 1:1.

8. The coating composition of claim 1, wherein a ratio of the niobium element to the sum of the carbon element and the non-metal element is about 1:1.

9. The coating composition of claim 1, wherein the composition has a hardness of at least approximately 10 GPa.

10. The coating composition of claim 1, wherein the composition has a hardness of at least approximately 20 GPa.

11. The coating composition of claim 1, wherein the composition has a Young's modulus of at least 300 GPa.

12. The coating composition of claim 1, wherein the composition has a Young's modulus of at least 400 GPa.

13. The coating composition of claim 1, the coating composition is produced by physical vapor deposition.

14. The coating composition of claim 1, wherein at least one physical property of the composition exhibits a monotonic dependence with respect to a content of the non-metal element, wherein the at least one property includes at least one of:
(i) a lattice constant;
(ii) a hardness;
(iii) a Young's modulus;
(iv) a thermal expansion coefficient;
(v) a thermal conductivity; and
(vi) a fracture toughness.

15. The coating composition of claim 1, wherein the composition has a columnar grain microstructure.

16. The coating composition of claim 1, wherein the composition has an average grain width of between approximately 10 nm and approximately 50 nm.

17. The coating composition of claim 1, wherein the forming of the second compound involves substitution of the carbon element with the non-metal element.

18. The coating composition of claim 1, wherein the composition has a compressive residual stress of at least 4.0 GPa.

19. The coating composition of claim 1, wherein at least a portion of the coating composition does not exhibit type I morphology.

20. An industrial tool comprising the coating composition of claim 1.

21. A composition, comprising:
a first compound comprising a first transition metal element and a carbon element; and
at least one second transition metal element that has a solubility lower than 10 atomic percent in the first compound.

22. The composition of claim 21, wherein the first transition metal element is niobium.

23. The composition of claim 21, wherein the first compound comprises niobium carbide.

24. The composition of claim 21, wherein the at least one second transition metal element is at least one of nickel and cobalt.

25. The composition of claim 21, wherein the at least one second transition metal element is in a form of a solid solution with at least some of the first transition metal element.

26. The composition of claim 21, wherein:
the at least one second transition metal element forms a solid solution with at least some of the first transition metal element;
the first compound has a first hardness value; and
the solid solution has a second hardness value that is lower than the first hardness value of the first compound.

27. The composition of claim 21, wherein the at least one second transition metal element is present at less than or equal to approximately 30 atomic %.

28. The composition of claim 21, wherein the composition has a grain size of less than or equal to approximately 50 nm.

29. The composition of claim 21, wherein the composition has a grain size of less than or equal to approximately 15 nm.

30. The composition of claim 21, wherein the composition has non-columnar structure.

31. The composition of claim 21, wherein the composition has a hardness of at least approximately 10 GPa.

32. The composition of claim 21, wherein the composition has a Young's modulus of at least 150 GPa.

33. The composition of claim 21, wherein the composition is a two-phase composite comprising a first phase comprising the first compound and a second phase comprising the transitional metal element.

34. The composition of claim 21, wherein the composition has a higher toughness compared to the same composition without the at least one second transition element.

35. The composition of claim 21, wherein at least one property of the composition exhibits a monotonic dependence with respect to a content of the non-metal element, and wherein the at least one property includes at least one of:
(i) a lattice constant;
(ii) a hardness;
(iii) a Young's modulus;
(iv) a thermal expansion coefficient;
(v) a thermal conductivity; and
(vi) a fracture toughness.

36. A method of forming a composition, the method comprising:
A) providing a substrate; and
B) disposing on the substrate a mixture of elements to form the composition, the mixture comprising niobium, carbon, and at least one additional element,
wherein B) involves deposition under a condition involving a processing intensity parameter.

37. The method of claim 36, wherein B) comprises disposing via physical vapor deposition.

38. The method of claim 36, wherein the at least one additional element includes at least one of a non-metal element and a transition metal element.

39. The method of claim 36, wherein the at least one additional element is nitrogen.

40. The method of claim 36, wherein the at least one additional element includes at least one of nickel and cobalt.

41. The method of claim 36, wherein the at least one additional element forms a solid solution with the niobium.

42. The method of claim 36, wherein the substrate comprises at least one of glass, silicon, steel, hard metal, solid carbide, and ceramic material.

43. The method of claim 36, further comprising heat treating the substrate.

44. The method of claim 36, wherein a ratio of the niobium to the carbon is approximately 1:1.

45. The method of claim 36, wherein a ratio of the niobium to a sum of the carbon and the additional element is approximately 1:1.

46. The method of claim 36, wherein the composition has a thickness of greater than or equal to approximately 400 nm.

47. The method of claim 36, wherein the composition has a hardness of at least approximately 10 GPa.

48. The method of claim 36, wherein the composition has a Young's modulus of at least 150 GPa.

49. The method of claim 36, wherein B) is carried out at a temperature less than approximately 550° C.

50. The method of claim 36, wherein the process intensity parameter comprises an applied bias and a deposition pressure.

51. A method of forming a composition, the method comprising:
A) sputtering, under a condition involving at least one processing intensity parameter comprising at least one of an applied bias and a deposition pressure, a mixture of niobium, carbon, and at least one additional element onto a substrate so as to form the composition; and
B) controlling the processing intensity parameter so as to affect at least one property of the composition.

52. The method of claim 51, wherein A) comprises sputtering by physical vapor deposition.

53. The method of claim 51, wherein in B), the at least one property comprises at least one of a hardness, a density, a residual stress, a Young's modulus, a structural integrity, a surface morphology, surface roughness and a lattice parameter.

54. The method of claim 51, wherein:
in B), the at least one property of the composition comprises at least one of a hardness, a residual stress, a density, and a Young's modulus; and
B) comprises increasing the at least one processing intensity parameter so as to increase a value of the at least one property.

55. The method of claim 51, wherein:
in B), the at least one property of the composition comprises at least one of a smoothness of surface topography, a density, and a compressive residual stress; and
B) comprises increasing the applied bias so as to increase a value of the at least one property.

56. A coating composition formed by a method comprising:
A) disposing on a substrate a mixture of elements to form the coating composition,
wherein the disposing involves deposition under a condition involving a processing intensity parameter; and
wherein the coating composition comprises a first compound comprising a niobium element, a carbon element, and at least one non-metal element that is capable of forming a second compound with the niobium element or a combination of the niobium element and the carbon element.

57. The coating composition of claim 56, wherein the mixture comprises niobium, carbon, and at least one additional element.

58. A coating composition formed by a method comprising:
A) disposing on a substrate a mixture of elements to form the coating composition,
wherein the disposing involves deposition under a condition involving a processing intensity parameter; and
wherein the coating composition comprises
a first compound comprising a first transition metal element and a carbon element; and
at least one second transition metal element that has a solubility lower than 10 atomic percent in the first compound.

59. An industrial tool comprising the coating composition of claim 58.
